(19) United States
(12) Patent Application Publication
(10) Pub. No.: US 2026/0255679 A1
(43) Pub. Date: Aug. 27, 2026

(54) ARRAY SUBSTRATE, DISPLAY PANEL AND DISPLAY DEVICE

(71) Applicants: CHENGDU BOE DISPLAY SCI-TECH CO., LTD., Chengdu, Sichuan (CN); BOE Technology Group Co., Ltd., Beijing (CN)

(72) Inventors: Cong ZHANG, Beijing (CN); Guidong YANG, Beijing (CN); Toshifumi YAGI, Beijing (CN); Jiajin LIU, Beijing (CN); Yuanhui GUO, Beijing (CN); Lei LIU, Beijing (CN); Junying XIAO, Beijing (CN); Yue GUAN, Beijing (CN); Honghui PENG, Beijing (CN)

(21) Appl. No.: 18/714,242

(22) PCT Filed: Aug. 29, 2023
(86) PCT No.: PCT/CN2023/115604

§ 371 Date: May 29, 2024

(51) Int. Cl. H10D 86/40; G02F 1/1362; G02F 1/1368; H10D 86/60

(52) U.S. Cl. CPC H10D 86/443; G02F 1/13624; G02F 1/136286; G02F 1/1368; H10D 86/60

(57) ABSTRACT

Disclosed are an array substrate, a display panel and a display device. The array substrate includes: a base substrate; a plurality of grid gates on a side of the base substrate, and the plurality of gate lines extend along the first direction; a plurality of data lines, the main body direction of the plurality of data lines extends along the second direction, the orthotropic projection of the data lines on the base substrate is curved in shape; a plurality of pixel electrodes, the orthotropic projection of the pixel electrodes on the base substrate is between the orthographic projections of adjacent data lines on the base substrate; each pixel electrodes include a plurality of slits, and the extension direction of orthotropic projection of slits is consistent with the extension direction of adjacent data lines on the base substrate.

### CROSS-REFERENCE TO RELATED APPLICATIONS

The application is a National Stage of International Application No. PCT/CN2023/115604, filed Aug. 29, 2023, which is hereby incorporated by reference in its entirety.

### TECHNICAL FIELD

The present disclosure relates to the field of semiconductor technology, in particular to an array substrate, a display panel and a display device.

### BACKGROUND

The name UV2A comes from the multiplication of ultraviolet (UV) and liquid crystal panel VA method, this technology can precisely control the alignment of liquid crystal molecules through ultraviolet light, which greatly improves the light transmittance.

The key to UV2A is to use a special polymer material as a orientation film to control the tilt of liquid crystal molecules along the ultraviolet direction with high precision. Its accuracy is measured in picometers (one trillion of a meter). The advantage of UV2A is that the LCD panel is a simple structure with no protrusions and no slits. This “liquid crystal technician's dream” was discussed 30 years ago. Today, this dream has been realized with the three conditions of new materials, production equipment and perfect processing process. The simple structure of the LCD panel not only improves production efficiency, but also has many advantages in image quality.

### SUMMARY

Embodiments of the disclosure provide an array substrate, a display panel and a display device. The array substrate includes:
a base substrate;
a plurality of gate lines on a side of the base substrate, and extending along a first direction;
a plurality of data lines, a main body direction of the plurality of data lines extends along a second direction, and an orthographic projection of each of the plurality of data lines on the base substrate is curved in shape;
a plurality of pixel electrodes, an orthographic projection of the pixel electrodes on the base substrate is between orthographic projections of adjacent data lines on the base substrate; each pixel electrode includes a plurality of slits, and an extension direction of an orthographic projection of one slit on the base substrate is identical to an extension direction of the orthographic projection of the adjacent data lines on the base substrate.

In some embodiments, an orthographic projection of the gate lines on the substrate passes through an central area of the orthographic projection of the pixel electrodes on the base substrate;
each pixel electrode includes a first gap in an area where the gate lines are located; each pixel electrode includes: a first pixel electrode located on one side of the gate line, a second pixel electrode on the other side of the gate line, and a connecting portion connecting at least a part of the first pixel electrode with at least a part of the second pixel electrode.

In some embodiments, the array substrate further includes: a plurality of transistors; the pixel electrodes are electrically connected with the data lines through the plurality of transistors;
the first pixel electrode includes: a first sub-pixel electrode distributed along the second direction, a second sub-pixel electrode distributed along the second direction; the second pixel electrode includes: a third sub-pixel electrode distributed along the second direction, a fourth sub-pixel electrode distributed along the second direction; where the second sub-pixel electrode is located on one side the first sub-pixel electrode far away from the data line that is electrically connected with the first sub-pixel electrode, and the fourth sub-pixel electrode is located on one side of the third sub-pixel electrode far away from the data line that is electrically connected with the third sub-pixel electrode;

one of the first sub-pixel electrode and the second sub-pixel electrode is electrically connected with one of the third sub-pixel electrode and the fourth sub-pixel electrodes through the connecting portion.

In some embodiments, the first sub-pixel electrode and the fourth sub-pixel electrode are electrically connected through the connecting portion in a layer where the pixel electrodes are located; the second sub-pixel electrode is independent of the third sub-pixel electrode in the layer where the pixel electrodes are located.

In some embodiments, the array substrate further includes: a first common wire that is located on a side of the gate line and extends along the first direction; the plurality of transistors includes: a first transistor, a second transistor, and a third transistor;
a control electrode of the first transistor is electrically connected with the gate lines, a first electrode of the first transistor is electrically connected with the data lines, and a second electrode of the first transistor is electrically connected with the connecting portion;
a control electrode of the second transistor is electrically connected with the gate line, a first electrode of the second transistor is electrically connected with the data line, and a second electrode of the second transistor is electrically connected with the second sub-pixel electrode and the third sub-pixel electrode;
a control electrode of the third transistor is electrically connected with the gate lines, the second electrode of the second transistor is multiplexed as a first electrode of the third transistor, and a second electrode of the third transistor is electrically connected with the first common wire.

In some embodiments, the second electrode of the first transistor includes: a first portion of the first transistor extending in the first direction;

the array substrate further includes: a first lap portion connected with the connecting portion, an orthographic projection of the first lap portion on the substrate and an orthographic projection of the first portion of the first transistor portion on the substrate have an overlapping area.

In some embodiments, the connecting portion includes: a first connecting portion extending along the first direction, a second connecting portion extending along the first direction, and a third connecting portion extending along the second direction;
one end of the first connecting portion is electrically connected with the first sub-pixel electrode, and the other end of the first connecting portion is electrically connected with one end of the third connecting portion; the other end of the third connecting portion is electrically connected with one end of the second connecting portion; the other end of the second connecting portion is electrically connected with the fourth sub-pixel electrode;
the first lap portion is electrically connected with one end of the first connecting portion which is far away from the first sub-pixel electrode connected with the first connecting portion.

In some embodiments, there is a second gap between the first connecting portion and the first sub-pixel electrode connected with the first connecting portion, and there is a third gap between the second connecting portion and the fourth sub-pixel electrode electrically connected with the second connecting portion.

In some embodiments, a length of the first lap portion in the second direction is greater than a length of the first connecting portion in the second direction.

In some embodiments, the second electrode of the second transistor includes: a first portion of a second transistor extending along the first direction and a second portion from which the first portion of the second transistor extends, of the second transistor extending along the second direction;
the array substrate further includes: a first adapter extending along the first direction, a second adapter extending along the second direction, and a second lap section; one end of the first adapter is electrically connected with the second sub-pixel electrode, and the other end of the first adapter is electrically connected with one end of the second adapter; the other end of the second adapter is electrically connected with the second lap portion; an orthographic projection of the second portion of the second transistor on the substrate and an orthographic projection of the second lap portion on the substrate have an overlapping area;
the array substrate further includes: a third adaptor along the first direction, and a third lap portion; one end of the third adapter is electrically connected with the third sub-pixel electrode, and the other end of the third adaptor is electrically connected with the third lap portion; an orthographic projection of the first portion of the second transistor on the substrate and an orthographic projection of the third lap portion on the substrate have an overlapping area.

In some embodiments, there is a fourth gap between the first adapter and the second sub-pixel electrode, and there is a fifth gap is between the third adapter and the third sub-pixel electrode.

In some embodiments, a length of the second lap portion in the first direction is greater than a length of the second adaptor in the first direction; and a length of the third lap portion in the second direction is greater than a length of the third adapter in the second direction.

In some embodiments, the second electrode of the third transistor includes: a first portion of the third transistor extending along the second direction, and a second portion from which the first portion of the third transistor extends, of the third transistor extending along the first direction;
the array substrate further includes: a fourth lap portion; the first common wire includes: a first-common-wire main portion and a first common lap portion connected with one end of the first-common-wire main portion;
an orthographic projection of the second portion of the third transistor on the base substrate and an orthographic projection of the fourth lap portion on the base substrate have an overlapping area; the orthographic projection of the first common lap portion on the base substrate and the orthographic projection of the fourth lap portion on the base substrate have an overlapping area.

In some embodiments, the fourth lap portion includes an outer edge of the fourth lap portion along the first direction, and the second lap portion includes an outer edge of the second lap portion extending along the first direction;
an extension line of the outer edge of the fourth lap portion coincides with an extension line of the outer edge of the second lap portion.

In some embodiments, the first lap portion includes an outer edge of the first lap portion extending along the second direction, and the third lap portion includes an outer edge of the third lap portion extending along the second direction;
an extension line of the outer edge of the first lap portion coincides with an extension line of the outer edge of the third lap portion.

In some embodiments, the array substrate further includes: a second common wiring group that is electrically connected with the first common wire and extends away from a side of the gate lines, where the second common wiring group includes: two second common wires; the orthographic projection of the data lines on the base substrate and orthographic projections of a gap between the two second common wires in the same second common wiring group on the base substrate have an overlapping areas;
the orthographic projection of the second common wire on the substrate is curved shape, and the curved shape of the orthographic projection of the second common wire on the base substrate is identical to the curved shape of the orthographic projection of the data lines on the base substrate.

In some embodiments, the array substrate further includes: a third common wire that is located on the other side of the gate line and extends along the first direction, and a fourth common wiring group that is connected with the third common wire and extends far away from a side of the gate lines;
the third common wire is disconnected at a position where the third common wire intersects with the data lines; the fourth common wiring group includes: two fourth common wires, the orthographic projection of the data lines on the base substrate and an orthographic projection of a gap between the two fourth common wires of the same fourth common wiring group on the base substrate have an overlapping area;
the orthographic projection of the fourth common wire on the base substrate is curved shape, and the curved shape of the orthographic projection of the fourth common wire on the base substrate is identical to the curved shape of the orthographic projection of the data lines on the base substrate.

In some embodiments, the first pixel electrode is an integrated structure, and the second pixel electrode is an integrated structure.

In some embodiments, one end far away from the gate lines, of the first pixel electrode is an opening; one end far away from the gate lines, of the second pixel electrode is an opening.

In some embodiments, a shape of the orthographic projection of the connecting portion on the base substrate is rectangular.

In some embodiments, each gate line includes a gate line hollow, an orthographic projection of the gate line hollow on the base substrate covers at least a part of the orthographic projection of the connecting portion on the base substrate.

In some embodiments, the first pixel electrode includes: a first sub-electrode portion distributed along the second direction, and a second sub-electrode portion distributed along the second direction, and an extension direction of the first sub-electrode portion is different from an extension direction of the second sub-electrode portion;
the second pixel electrode includes: a third sub-electrode portion along the second direction, and a fourth sub-electrode portion along the second direction; an extension direction of the third sub-electrode portion is different from an extension direction of the fourth sub-electrode portion.

In some embodiments, the extension direction of the first sub-electrode portion is identical to the extension direction of the fourth sub-electrode portion; the extension direction of the second sub-electrode portion is identical to the extension direction of the third sub-electrode portion.

In some embodiments, the extension direction of the first sub-electrode portion is identical to the extension direction of the third sub-electrode portion; the extension direction of the second sub-electrode portion is identical to the extension direction of the fourth sub-electrode portion.

In some embodiments, an extension direction of the slits in the first sub-electrode portion is identical to the extension direction of the first sub-electrode portion;
an extension direction of the slits in the second sub-electrode portion is identical to the extension direction of the second sub-electrode portion;
an extension direction of the slits in the third sub-electrode portion is identical to the extension direction of the third sub-electrode portion;
an extension direction of the slits in the fourth sub-electrode portion is identical to the extension direction of the fourth sub-electrode portion.

In some embodiments, each data line includes: a first data portion located on a side of the first sub-electrode portion and extending in a direction same as the extension direction of the first sub-electrode portion, a second data portion located on one side of the second sub-electrode portion and extending in a direction same as the extension direction of the second sub-electrode portion, a third data portion located on one side of the third sub-electrode portion and extending in a direction same as the extension direction of the third sub-electrode portion, and a fourth data portion located on one side of the fourth sub-electrode portion and extending in a direction same as the extension direction of the fourth sub-electrode portion.

In some embodiments, each data line further includes: a fifth data portion extending along the second direction and connecting the second data portion with the third data portion.

In some embodiments, the first pixel electrode and the second pixel electrode extend along a third direction, and an outer edge of the first pixel electrode in the extension direction does not coincide with an outer edge of the second pixel electrode in the extension direction.

In some embodiments, each data line includes: a sixth data portion arranged at a side of the first pixel electrode and a seventh data portion arranged at a side of the second pixel electrode;
an extension direction of the sixth data portion is identical to an extension direction of the seventh data portion, and an extension line of the sixth data portion does not coincide with an extension line of the seventh data portion.

In some embodiments, each data line further includes: an eighth data portion extending along the second direction and connecting the sixth data portion with the seventh data portion.

In some embodiments, the orthographic projection of the gate lines on the base substrate is on a side of the orthographic projection of the pixel electrode on the base substrate.

In some embodiments, the array substrate further includes: a first conductive layer arranged on a side facing the base substrate, of the pixel electrode, and a fifth common wire in a layer same as the layer where the gate liens are located; the first conductive layer is electrically connected with the fifth common wire through a conduction hole.

In some embodiments, the fifth common wire includes a first common convex portion on a side facing the gate lines, of the fifth common wire; at least parts of orthographic projection of the first common convex portion on the base substrate overlaps at least parts of orthographic projection of the conduction hole on the base substrate.

In some embodiments, each gate line includes a first notch on a side facing the fifth common wire, of the gate line, the first notch is opposite to the first common convex portion.

In some embodiments, one side of the pixel electrode is provided with a fifth lap portion;
each gate line includes a second notch on a side facing the fifth common wire, of the gate line; an orthographic projection of the second notch on the base substrate covers the orthographic projection of the fifth lap portion on the base substrate.

In some embodiments, the pixel electrode includes: a first sub-electrode portion, a second sub-electrode portion, a third sub-electrode portion, and a fourth sub-electrode portion sequentially distributed in the second direction;
an extension direction of the first sub-electrode portion is different from an extension direction of the second sub-electrode portion; an extension direction of the third sub-electrode portion is different from an extension direction of the fourth sub-electrode portion.

In some embodiments, the extension direction of the first sub-electrode is identical to the extension direction of the fourth sub-electrode portion; the extension direction of the second sub-electrode portion is identical to the extension direction of the third sub-electrode portion.

In some embodiments, each data line includes: a first data portion located on a side of the first sub-electrode portion and extending in a direction same as the extension direction of the first sub-electrode portion, a second data portion located on a side of the second sub-electrode portion and extending in a direction same as the extension direction of the second sub-electrode portion, a third data portion located on a side of the third sub-electrode portion and extending in a direction same as the extension direction of the third sub-electrode portion, and a fourth data portion located on a side of the fourth sub-electrode portion and extending in a direction same as the extension direction of the fourth sub-electrode portion; the second data portion is directly connected with the third data portion.

In some embodiments, each pixel electrode includes: a fifth sub-electrode portion, a sixth sub-electrode portion, and a seventh sub-electrode portion which are distributed in sequence in the second direction; an extension direction of the fifth sub-electrode portion is identical to an extension direction of the seventh sub-electrode portion; an extension direction of the sixth sub-electrode portion is different from the extension direction of the fifth sub-electrode portion;
an extension length of the sixth sub-electrode portion is greater than an extension length of the fifth sub-electrode portion, and the extension length of the sixth sub-electrode portion is greater than an extension length of the seventh sub-electrode portion.

In some embodiments, each data line includes: a ninth data portion located on a side of the fifth sub-electrode portion and extending in a direction same as the extension direction of the fifth sub-electrode portion, a tenth data portion located on a side of the sixth sub-electrode portion and extending in a direction same as the extension direction of the sixth sub-electrode portion, and an eleventh data portion located on a side of the seventh sub-electrode portion and extending in a direction same as the extension direction of the seventh sub-electrode portion.

An embodiment of the present disclosure further provides a display panel, including the array substrate as mentioned in above embodiments, and further including an opposing substrate arranged as opposed to the array substrate, where the opposing substrate comprises a common electrode layer.

An embodiment of the present disclosure further provides a display device, including the display panel as mentioned in above embodiments.

### BRIEF DESCRIPTION OF FIGURES

FIG. 1A is one of the schematic diagrams of the array substrate provided by an embodiment of the present disclosure.

FIG. 1B is an enlarged schematic diagram of the dashed-line frame S1 in FIG. 1A.

FIG. 1C is a schematic diagram of the single layer where the gate line is located in FIG. 1A.

FIG. 1D is a schematic diagram of a single layer of an active layer in FIG. 1A.

FIG. 1E is a schematic diagram of the single layer where the data line is located in FIG. 1A.

FIG. 1F is a schematic diagram of the single layer of the first insulating layer in FIG. 1A.

FIG. 1G is a schematic diagram of the single layer where the pixel electrode is located in FIG. 1A.

FIG. 1H is a schematic diagram of the black matrix layer corresponding to FIG. 1A.

FIG. 1I is a schematic view of the cross-section along the dashed line EF in FIG. 1B.

FIG. 2A is the second schematic diagram of the array substrate provided by an embodiment of the present disclosure.

FIG. 2B is an enlarged schematic diagram of the dashed-line frame S1 in FIG. 2A.

FIG. 2C is a schematic diagram of the single layer where the gate line is located in FIG. 2A.

FIG. 2D is a schematic diagram of a single layer of an active layer in FIG. 2A.

FIG. 2E is a schematic diagram of the single layer where the data line is located in FIG. 2A.

FIG. 2F is a schematic diagram of the single layer of the first insulating layer in FIG. 2A.

FIG. 2G is a schematic diagram of the single layer of the first conductive layer in FIG. 2A.

FIG. 2H is a schematic diagram of the second insulating layer corresponding to FIG. 2A.

FIG. 2I is a schematic diagram of the pixel electrode layer corresponding to FIG. 2A.

FIG. 2J is a schematic diagram of the black matrix layer corresponding to FIG. 2A.

FIG. 3A is the third schematic diagram of the array substrate provided by an embodiment of the present disclosure.

FIG. 3B is an enlarged schematic diagram of the dashed-line frame S1 in FIG. 3A.

FIG. 3C is a schematic diagram of the single layer where the gate line is located in FIG. 3A.

FIG. 3D is a schematic diagram of a single layer of an active layer in FIG. 3A.

FIG. 3E is a schematic diagram of the single layer where the data line is located in FIG. 3A.

FIG. 3F is a single layer schematic diagram of the first insulating layer in FIG. 3A.

FIG. 3G is a schematic diagram of the single layer of the first conductive layer in FIG. 3A.

FIG. 3H is a schematic diagram of the second insulating layer corresponding to FIG. 3A.

FIG. 3I is a schematic diagram of the pixel electrode layer corresponding to FIG. 3A.

FIG. 3J is a schematic diagram of the black matrix layer corresponding to FIG. 3A.

FIG. 4A is the fourth schematic diagram of the array substrate provided by an embodiment of the present disclosure.

FIG. 4B is an enlarged schematic diagram of the dashed-line frame S1 in FIG. 4A.

FIG. 4C is a schematic diagram of the single layer where the gate line is located in FIG. 4A.

FIG. 4D is a schematic diagram of a single layer of an active layer in FIG. 4A.

FIG. 4E is a schematic diagram of the single layer where the data line is located in FIG. 4A.

FIG. 4F is a schematic diagram of the single layer of the first insulating layer in FIG. 4A.

FIG. 4G is a schematic diagram of the single layer of the first conductive layer in FIG. 4A.

FIG. 4H is a schematic diagram of the second insulating layer corresponding to FIG. 4A.

FIG. 4I is a schematic diagram of the pixel electrode layer corresponding to FIG. 4A.

FIG. 4J is a schematic diagram of the black matrix layer corresponding to FIG. 4A.

FIG. 5A is the fifth schematic diagram of the array substrate provided for the embodiment of the present disclosure.

FIG. 5B is an enlarged schematic diagram of the dashed-line frame S1 in FIG. 5A.

FIG. 5C is a schematic diagram of the single layer where the gate line is located in FIG. 5A.

FIG. 5D is a schematic diagram of a single layer of an active layer in FIG. 5A.

FIG. 5E is a schematic diagram of the single layer where the data line is located in FIG. 5A.

FIG. 5F is a schematic diagram of the single layer of the first insulating layer in FIG. 5A.

FIG. 5G is a schematic diagram of the single layer of the first conductive layer in FIG. 5A.

FIG. 5H is a schematic diagram of the second insulating layer corresponding to FIG. 5A.

FIG. 5I is a schematic diagram of the pixel electrode layer corresponding to FIG. 5A.

FIG. 5J is a schematic diagram of the black matrix layer corresponding to FIG. 5A.

FIG. 6 is a simulation diagram of the luminous effect of the display panel of the UV2A orientation mode at a sub-pixel.

FIG. 7 is a simulation diagram of the luminous effect of the display panel of the SUVA orientation mode at a sub-pixel.

FIG. 8 is a simulation diagram of the luminous effect of the display panel of the SUVA-ADS orientation mode at a sub-pixel when the data line is vertically routed.

FIG. 9 is a simulation diagram of the luminous effect of a display panel at a sub-pixel provided by an embodiment of the present disclosure.

FIG. 10 is a schematic diagram of the liquid crystal orientation at a sub-pixel of the display panel of the UV2A orientation mode.

FIG. 11 is a schematic diagram of the liquid crystal orientation of the display panel at a sub-pixel provided by an embodiment of the present disclosure.

### DETAILED DESCRIPTION

In order to make the purpose, technical solution and advantages of embodiments of the present disclosure clearer, the technical solutions of embodiments of the present disclosure will be clearly and completely described below in conjunction with the accompanying drawings of embodiments of the present disclosure. Obviously, embodiments described are some embodiments of the present disclosure, not all embodiments. Based on embodiments of the present disclosure described, all other embodiments obtained by a person skilled in the art without creative labor are within the scope of protection of the present disclosure. Implementation can take a number of different forms. A person of ordinary skill in the art to which he belongs can easily understand the fact that the means and contents may be transformed into one or more forms without departing from the purpose and scope of the present disclosure. Therefore, this disclosure should not be construed as confined to the contents described in the following embodiments. Without conflict, embodiments in the present disclosure and the features in embodiments may be arbitrarily combined with each other.

Unless otherwise defined, the technical or scientific terms used in this disclosure shall have the ordinary meaning understood by persons with general skill in the field to which this disclosure belongs. The terms “first”, “second” and similar terms used in this disclosure do not indicate any order, number or importance, but merely to distinguish between the different components. Words such as “include” or “comprise” mean that the element or object that precedes the word includes the element or object listed after the word and its equivalents, and does not exclude other elements or objects. Similar terms such as “connection” or “link” are not limited to physical or mechanical connections, but may include electrical connections, whether direct or indirect.

As used herein, the words “approximately” or “substantially the same” include the stated values and imply an acceptable deviation from the specific values as determined by a person of ordinary skill in the art taking into account the measurements in question and the errors associated with the measurements of the specific quantities (i.e., the limitations of the measurement system). For example, “substantially the same” can mean that the difference from the stated value is within one or more standard deviations, or within the range of ±30%, 20%, 10%, and 5%. In this manual, “substantially the same” can refer to cases where the values differ by less than 10%.

In the attached drawing, the thickness of layers, films, panels, areas, etc., is enlarged for clarity. In this article, an exemplary embodiment is described with reference to a cross-sectional diagram that is a schematic diagram of an idealized embodiment. In this way, deviations from the shape of the diagram are expected as a result of, for example, manufacturing techniques and/or tolerances. Therefore, the embodiments described in this disclosure should not be construed as being limited to the specific shape of the area shown herein, but rather as including deviations in the shape caused by, for example, manufacturing. For example, an area that is illustrated or described as flat can typically have rough and/or non-linear characteristics. In addition, the sharp corners shown can be round. Thus, the areas shown in the diagram are inherently schematic, and their shapes do not purport the precise shape of the illustrated areas and are not intended to limit the scope of the claims.

In this specification, for convenience, the use of words and phrases indicating orientations or positional relationships, such as “middle”, “up”, “down”, “vertical”, “horizontal”, “top”, “bottom”, “inside”, “outside”, etc., to illustrate the positional relationships of the constituent elements with reference to the accompanying drawings, is only for the convenience of describing this description and simplifying the description, and does not indicate or imply that the device or element referred to must have a specific orientation, be constructed and operated in a particular orientation, and therefore cannot be construed as limiting the present disclosure. The positional relationships of the constituent elements change appropriately according to the direction in which the constituent elements are described. Therefore, it is not limited to the words and phrases stated in the manual, and can be replaced appropriately according to the situation.

In this specification, unless otherwise expressly specified or limited, the terms “mounted”, “connected” and “connecting” shall be construed broadly. For example, it can be a fixed connection, or a detachable connection, or a one-piece connection; it can be mechanically connected, or electrically connected; it can be directly connected, indirectly connected by middleware, or connected within two components. For those of ordinary skill in the art, the meaning of the above terms in the present disclosure may be understood as appropriate.

In this specification, “electrical connection” includes a situation in which the constituent elements are connected together by elements that have some electrical effect. There are no special restrictions on “elements with a certain electrical function” as long as they can transmit electrical signals between the constituent elements of the connection. Examples of “components with some electrical function” include not only electrodes and wiring, but also switching elements such as transistors, resistors, inductors, capacitors, and other components with one or more functions.

In this specification, a transistor is a component that includes at least three terminals: a gate electrode (gate), a drain electrode, and a source electrode. Transistors have a channel area between the drain electrode (drain terminal, drain area, or drain) and the source electrode (source terminal, source area, or source), and current can flow through the drain electrode, channel area, and source electrode. In the present disclosure, a channel area refers to the area through which the current flows primarily.

In addition, the gate of a transistor can be called a control electrode. In the case of the use of transistors of opposite polarity, or in the case of changes in the direction of the current during circuit operation, the functions of the “source electrode” and “drain electrode” may be reversed. Therefore, in this specification, the “source electrode” and “drain electrode” can be interchanged.

In this specification, “parallel” refers to a state in which two straight lines form an angle of −10° or more and less than 10°, so it can include a state in which the angle is more than −5° and less than 5°. In addition, “perpendicular” refers to the state in which the angle formed by two straight lines is 80°or more and less than 100°, so it can include an angle of 85° or more and an angle of 95° or less.

In this specification, triangles, rectangles, trapezoids, pentagons or hexagons are not strictly sense, they can be approximate triangles, rectangles, trapezoids, pentagons or hexagons, etc., and there can be some small deformations caused by tolerances, and there can be guide angles, arc edges and deformations.

In this specification, “film” and “layer” can be interchangeable. For example, you can sometimes replace “conductive layer” with “conductive film”. In the same way, it is sometimes possible to replace “insulating film” with “insulating layer”.

In order to keep the following descriptions of the embodiments of the present disclosure clear and concise, the detailed descriptions of known functions and known parts are omitted.

The key to UV2A is to use a special polymer material as an orientation film to control the tilt of liquid crystal molecules along the ultraviolet direction with high precision. However, this light orientation method has its own disadvantage, that is, the color shift is poor.

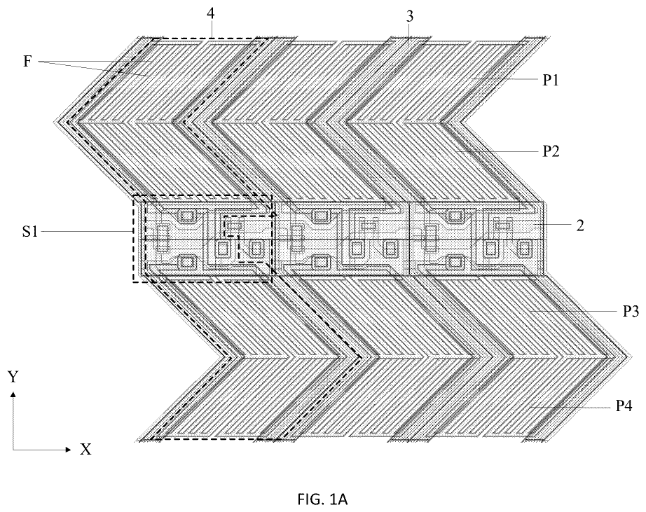

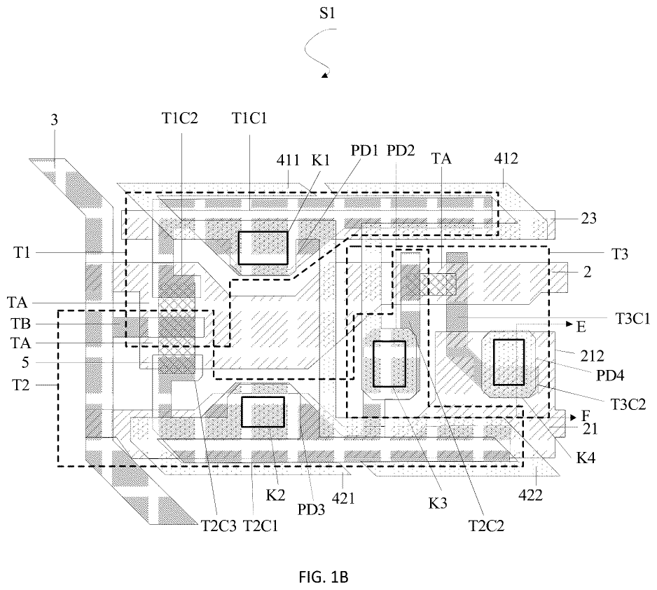

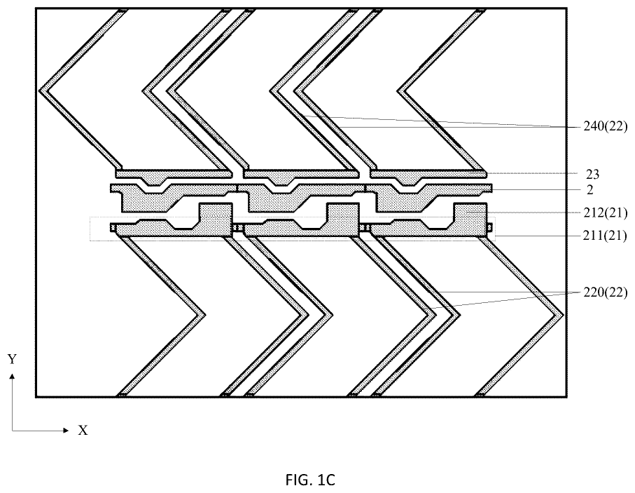

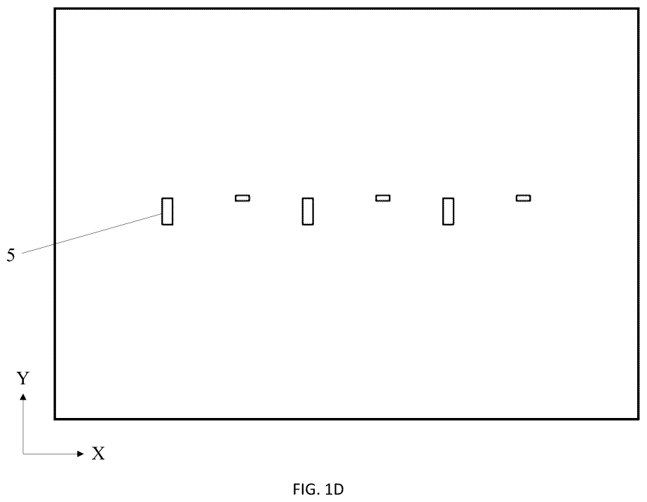

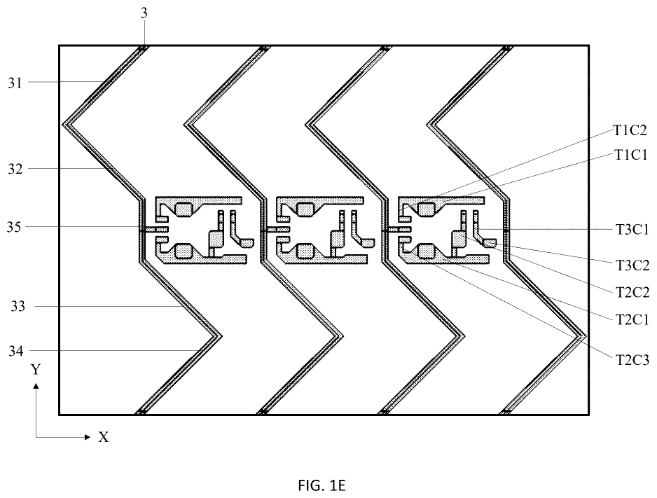

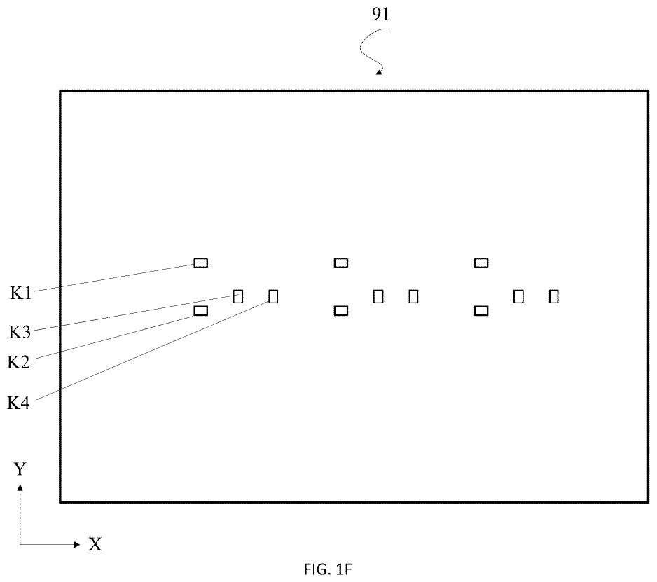

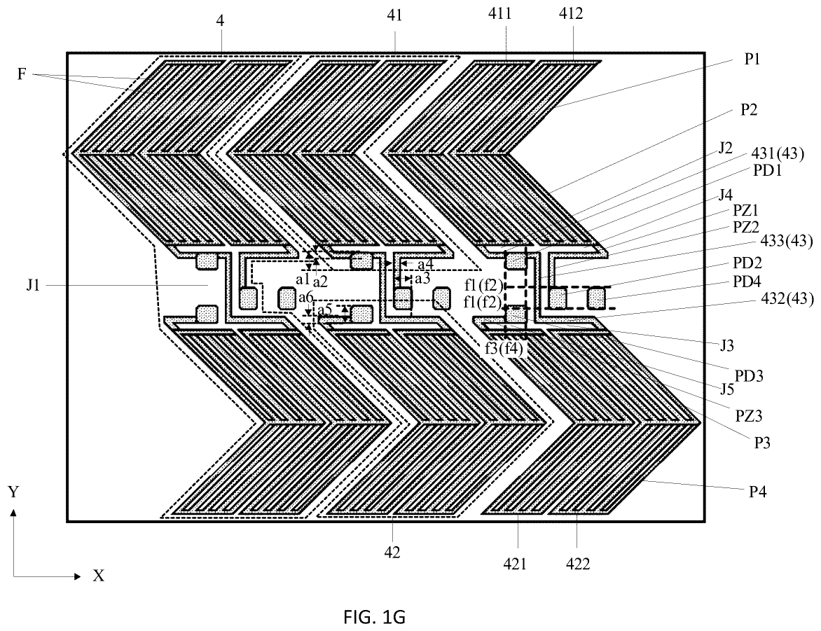

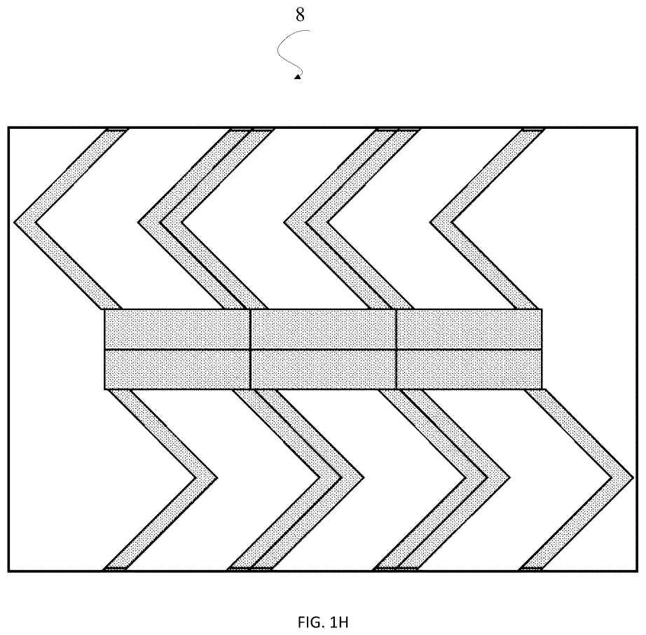

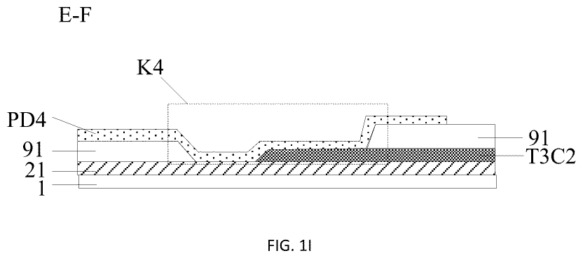

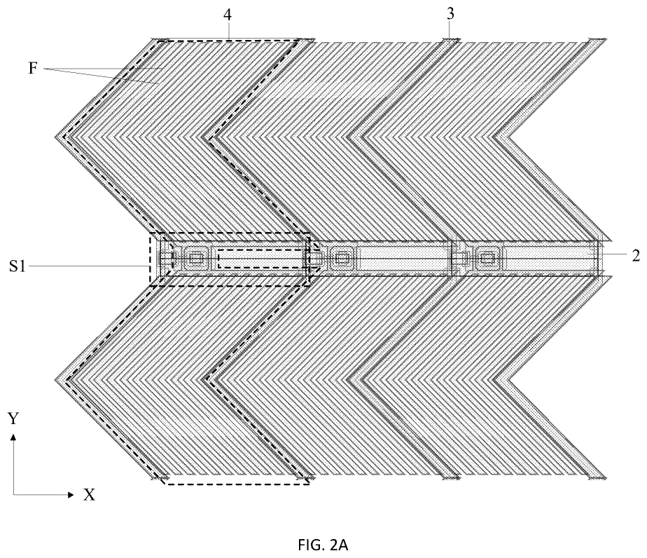

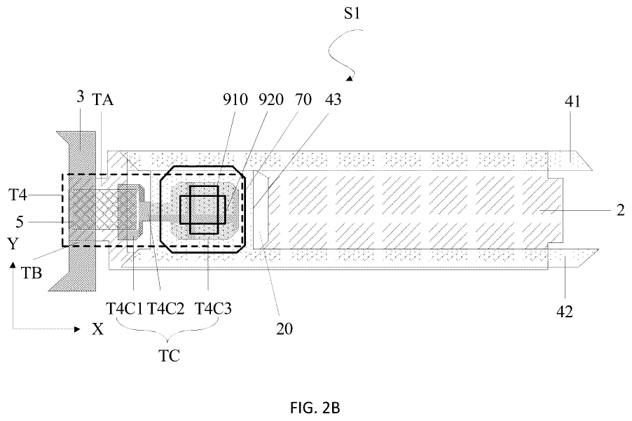

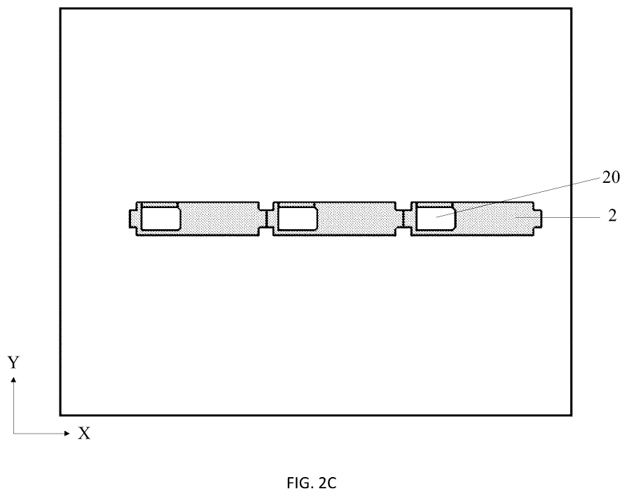

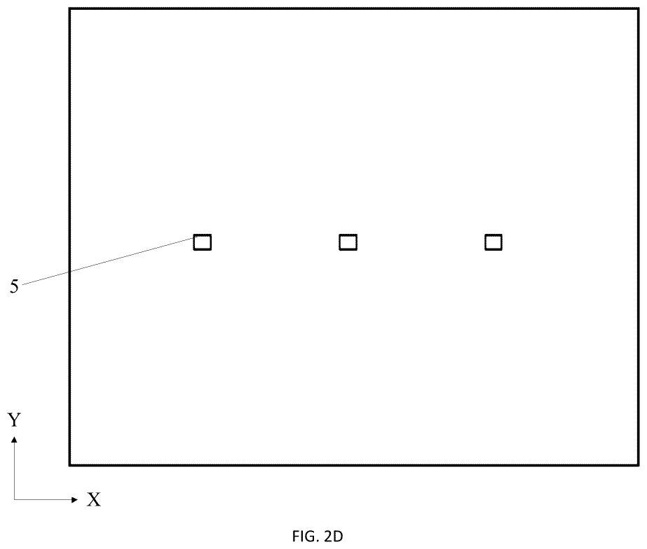

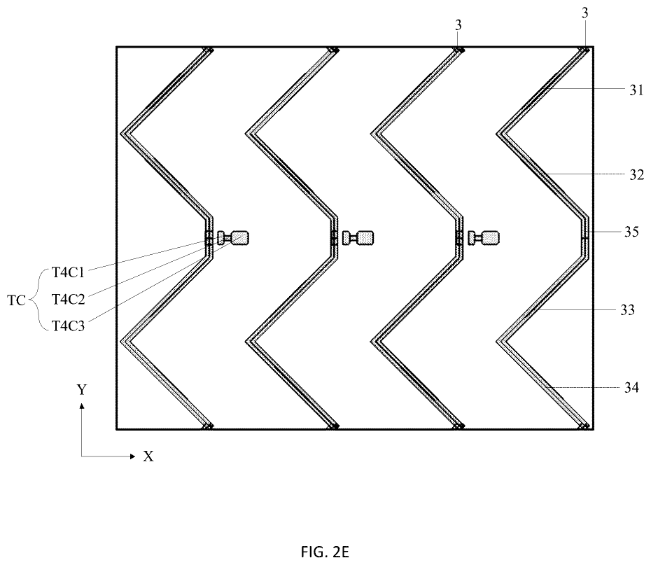

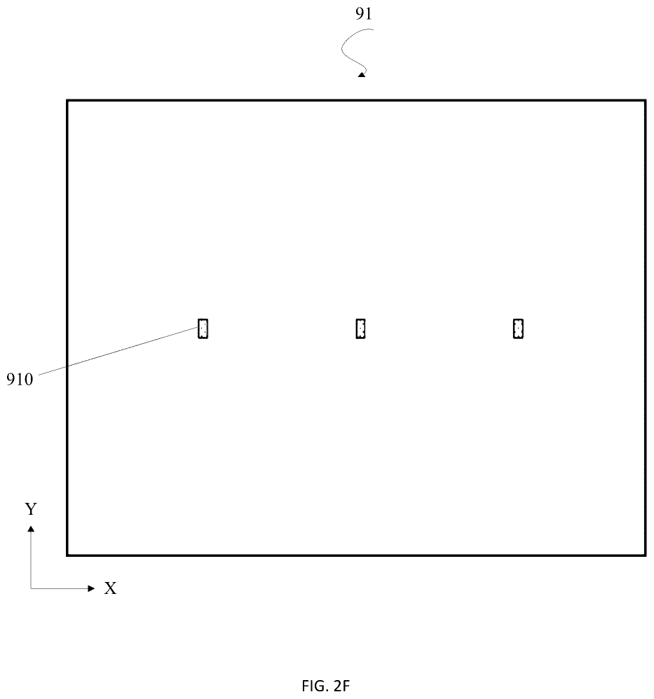

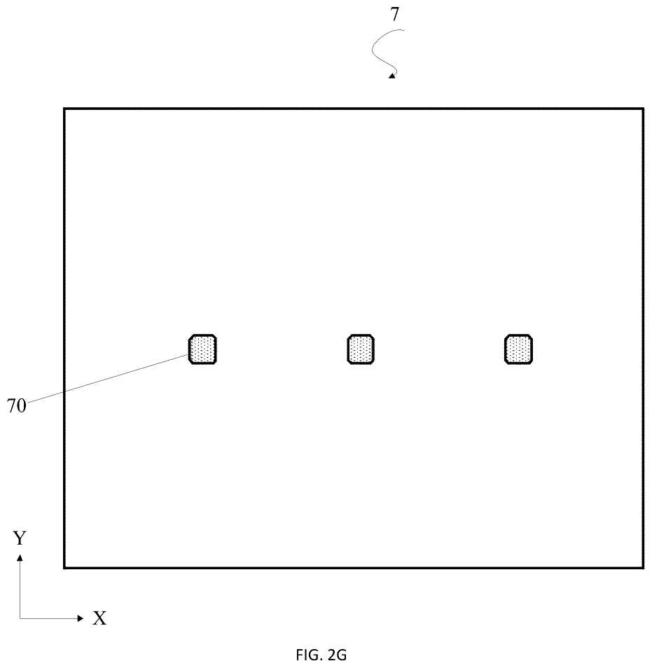

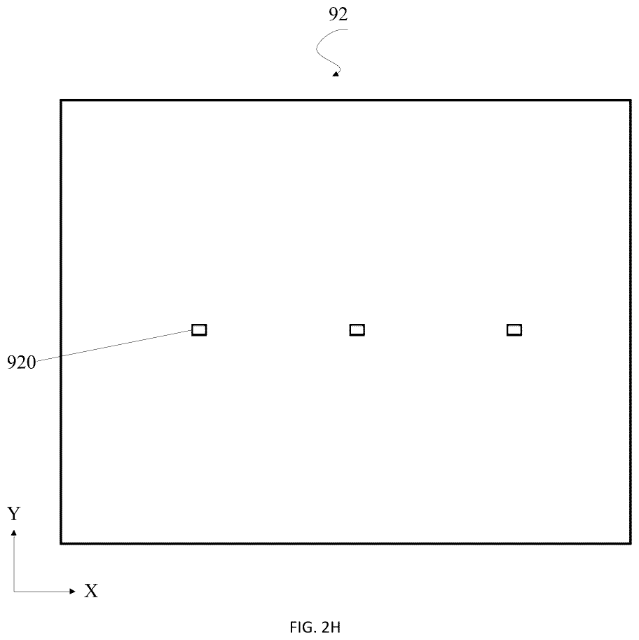

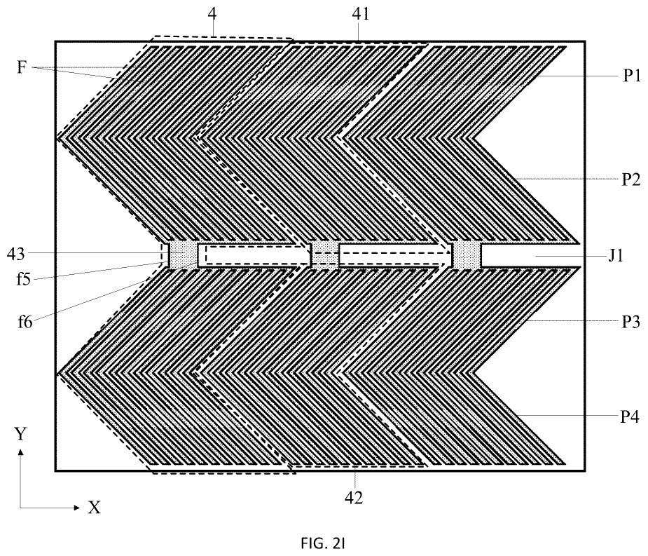

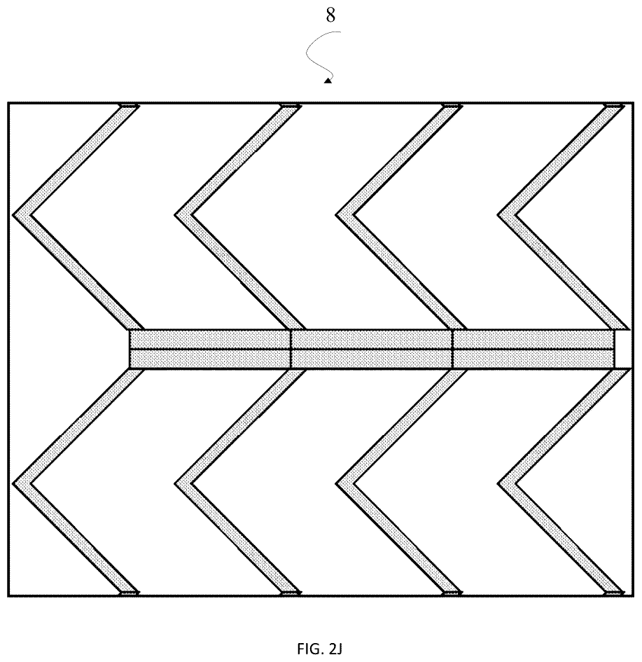

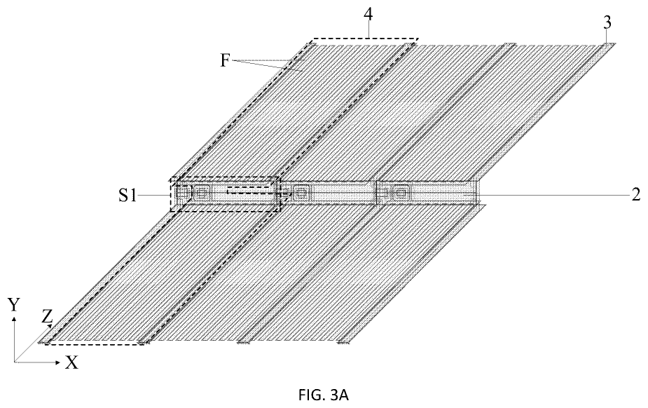

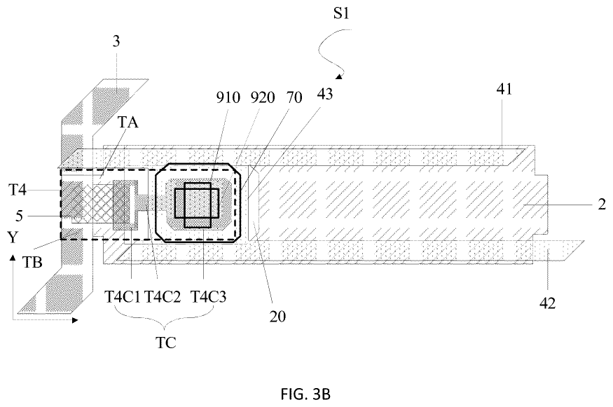

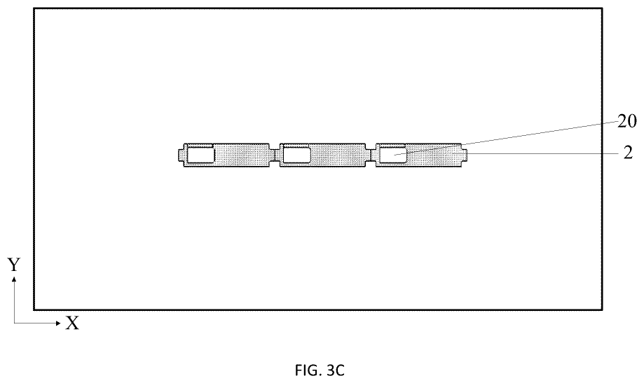

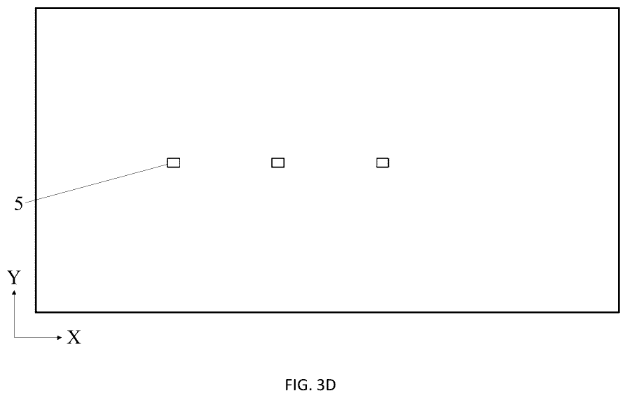

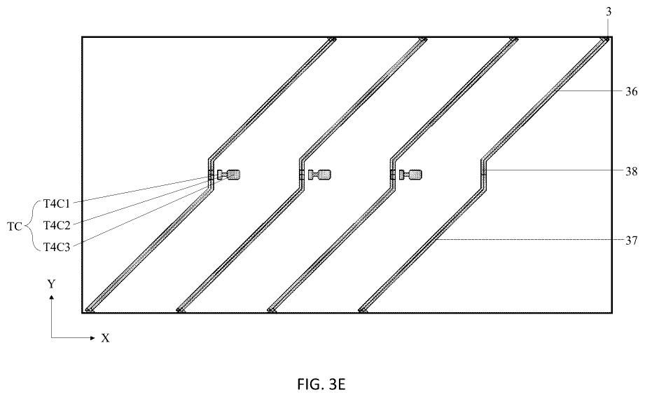

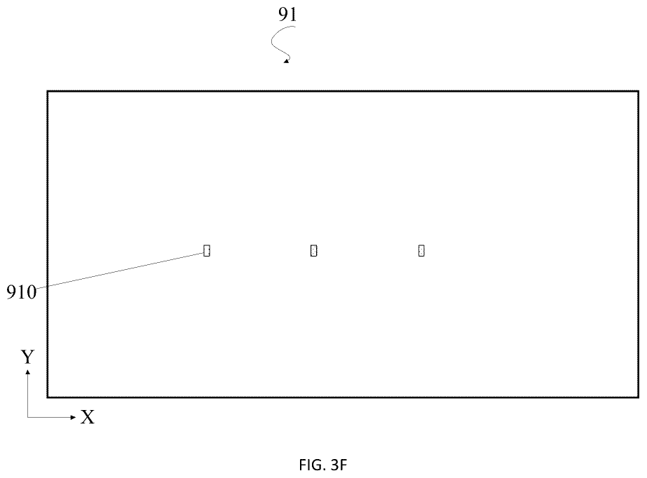

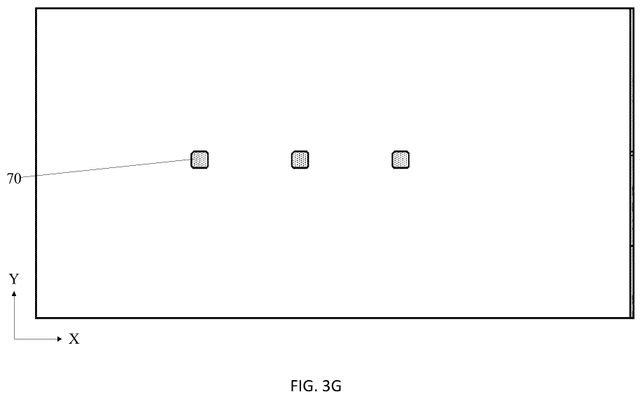

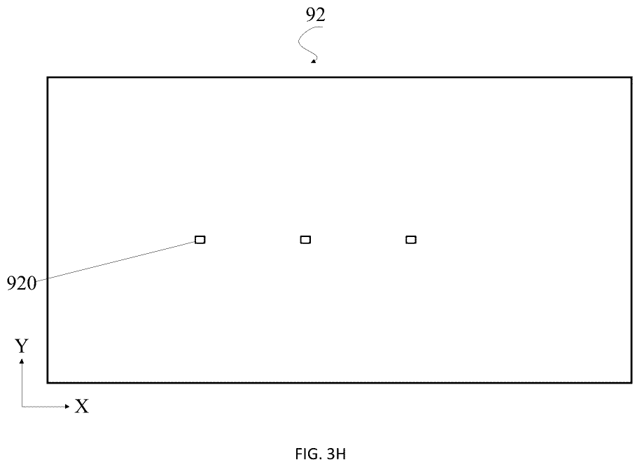

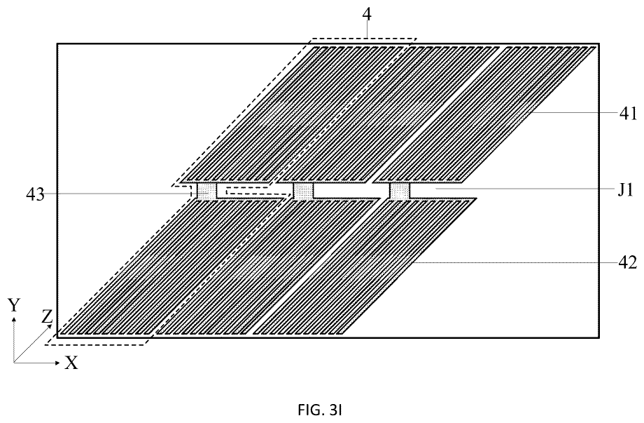

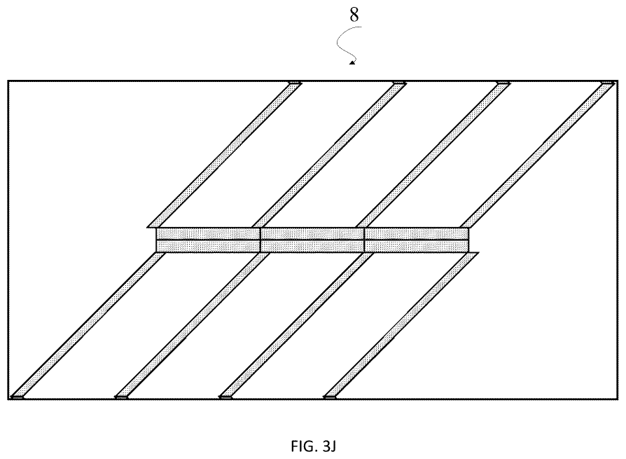

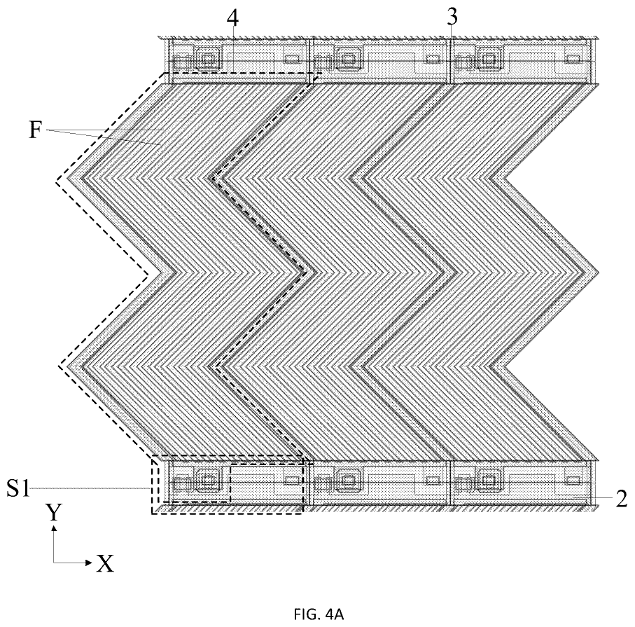

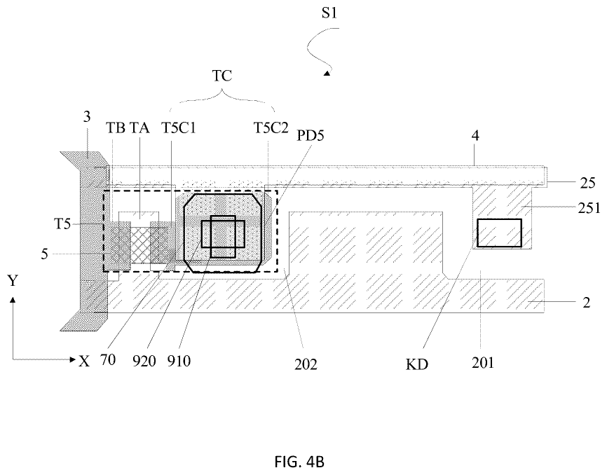

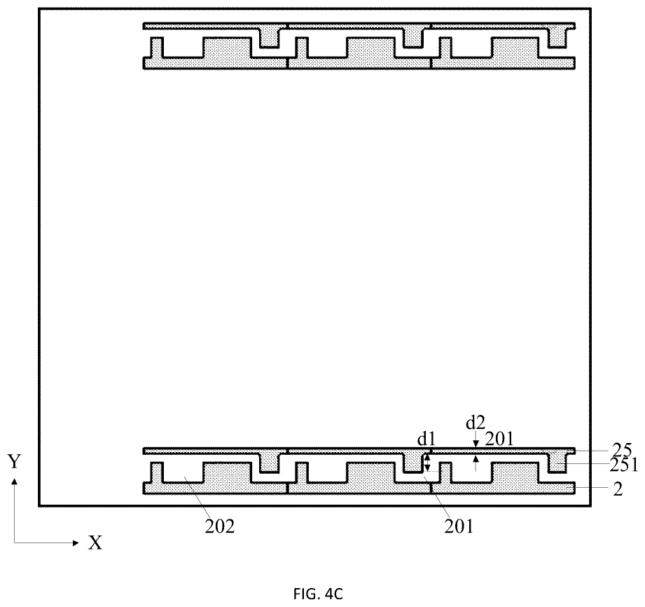

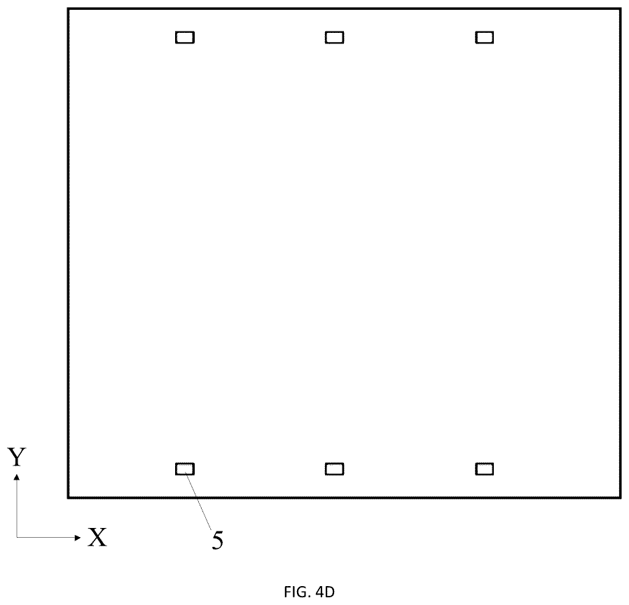

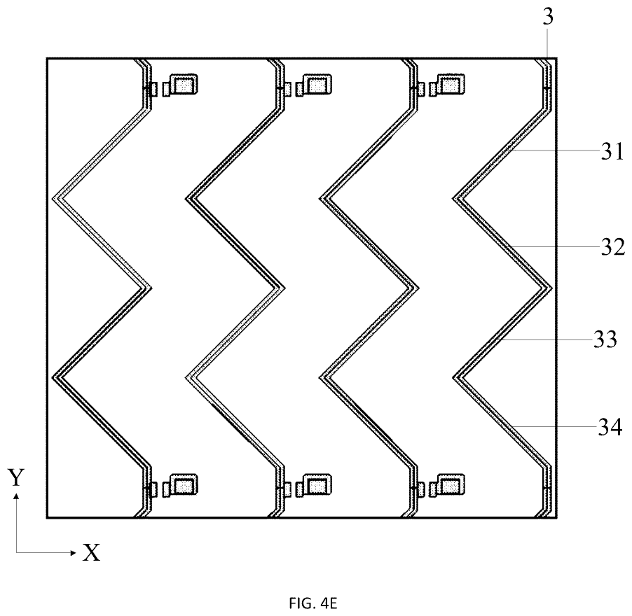

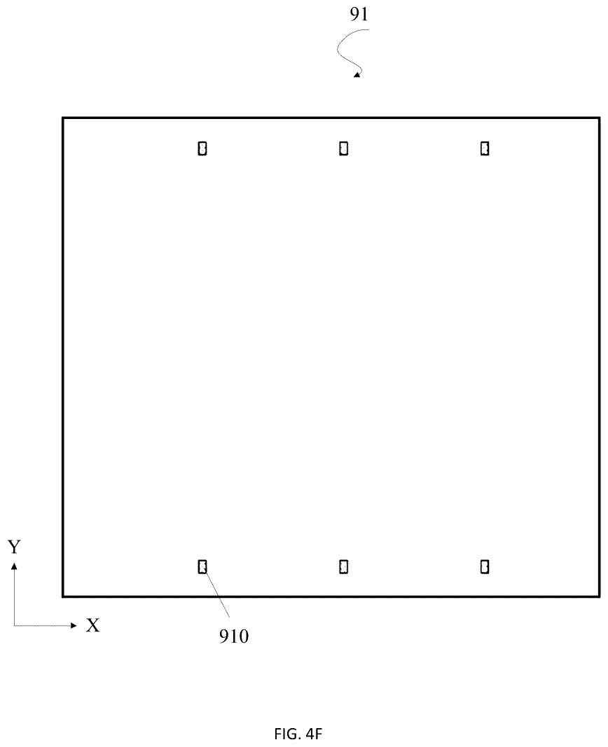

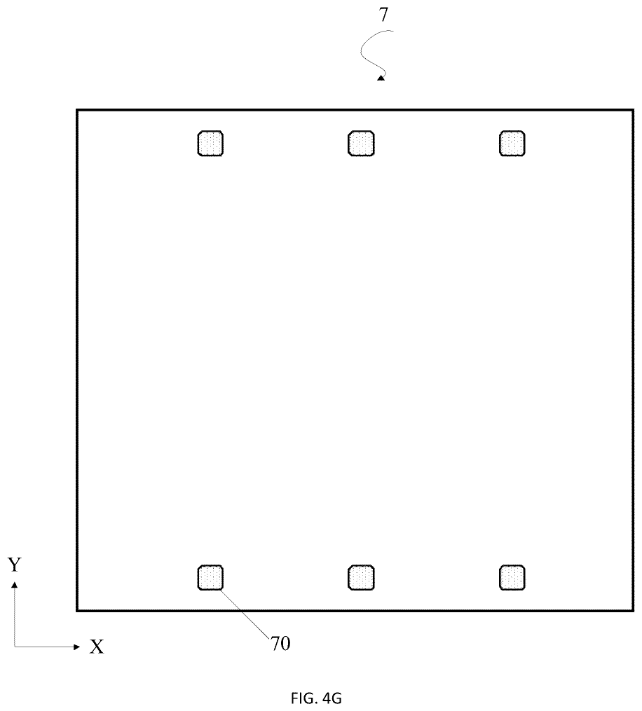

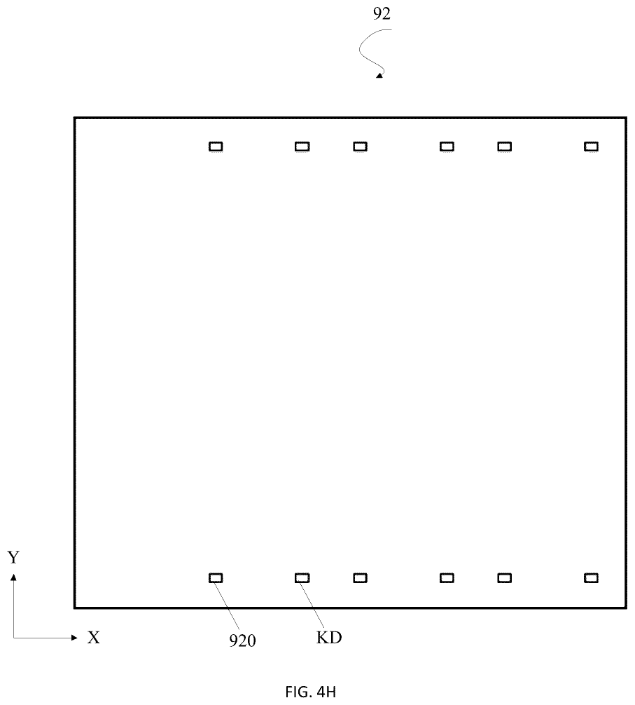

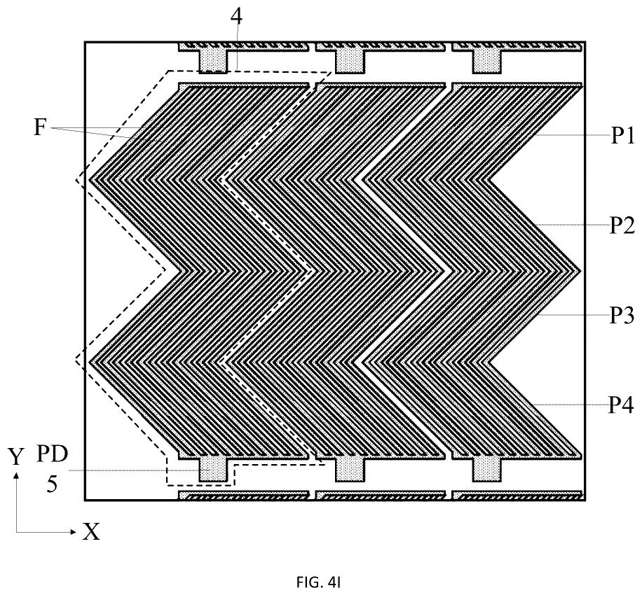

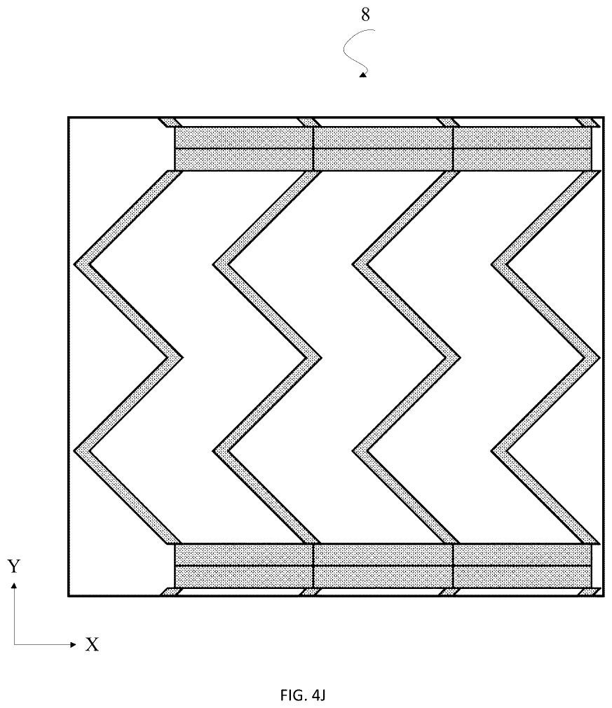

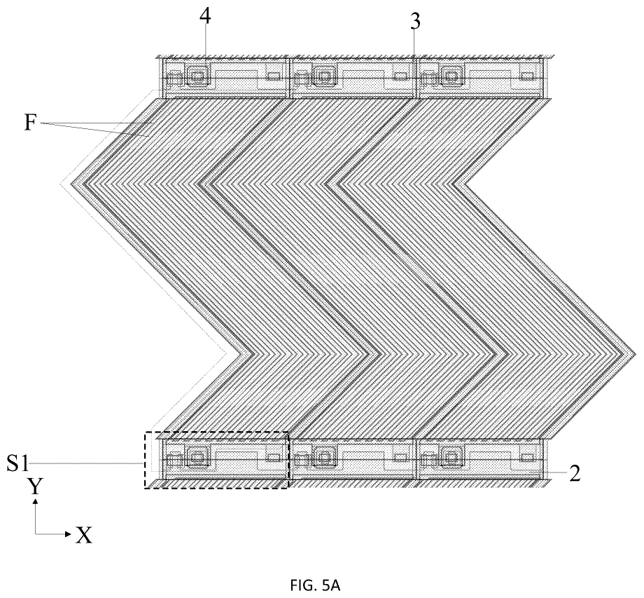

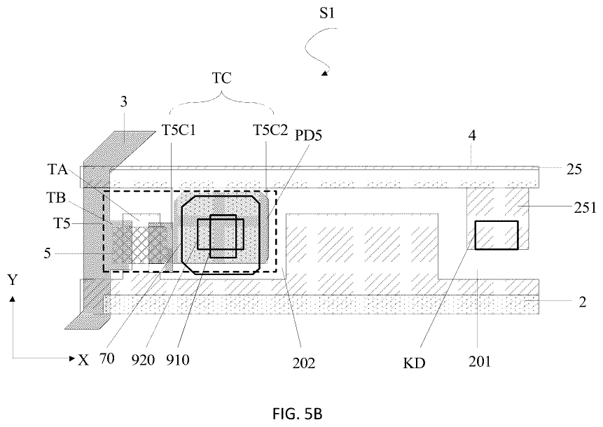

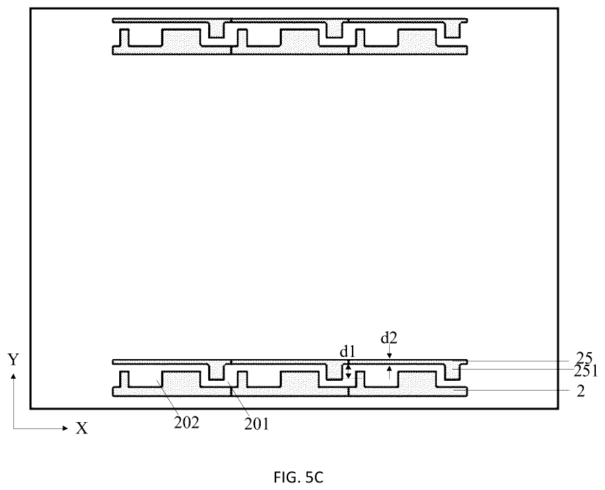

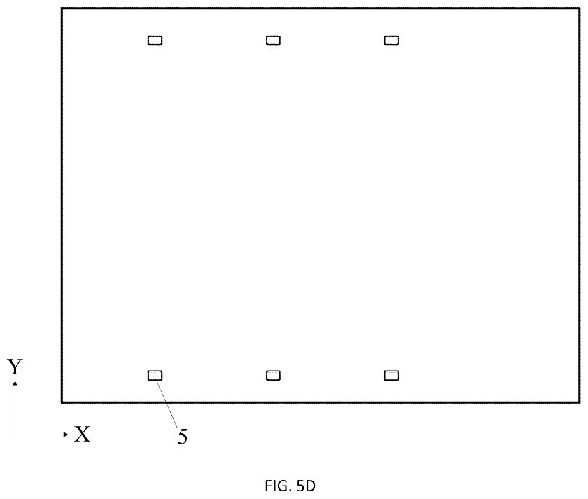

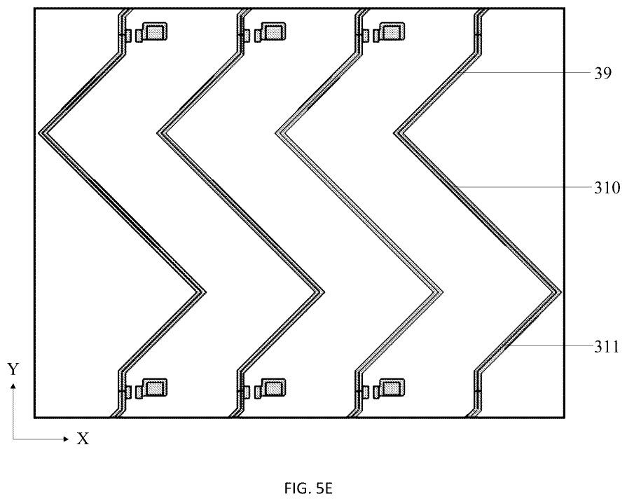

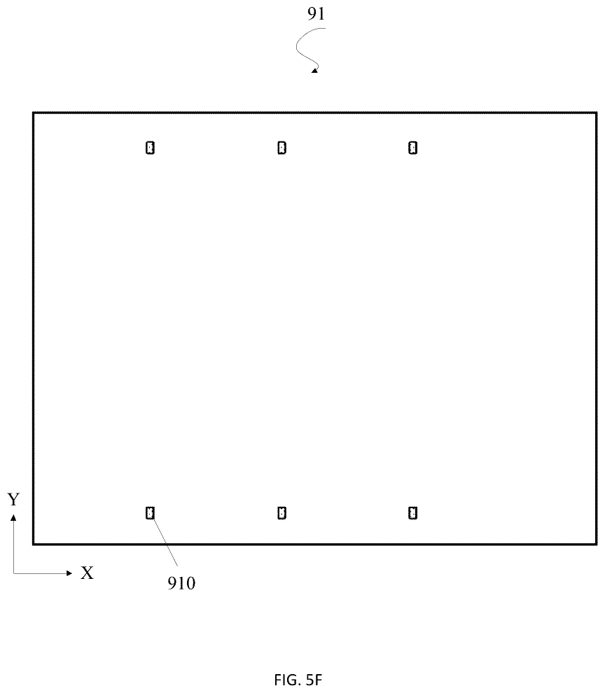

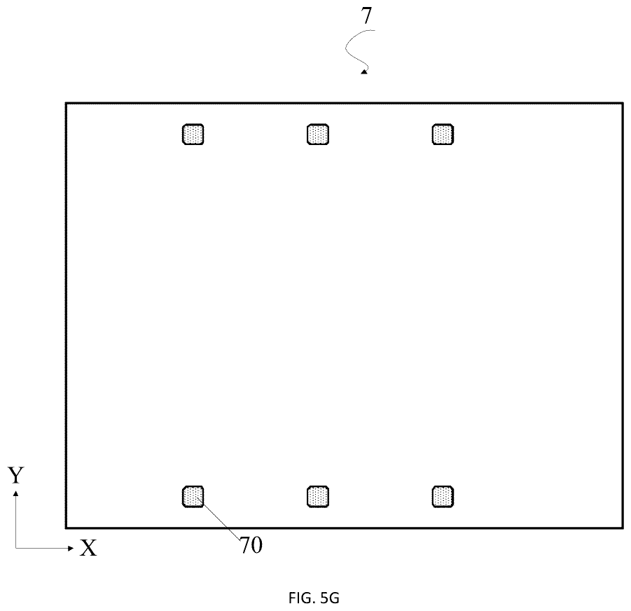

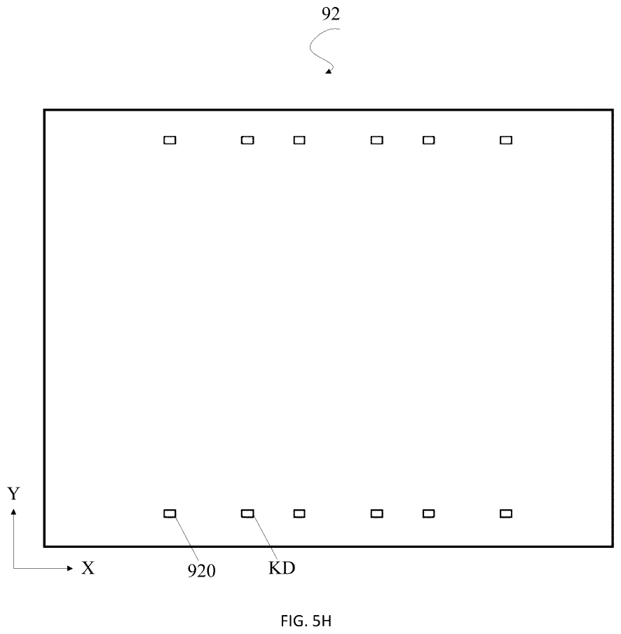

In view of this, refer to FIGS. 1A to 1H, 2A to 2J, 3A to 3J, 4A to 4J, and 5A to 5J. FIG. 1A is the first schematic diagram of the array substrate provided by an embodiment of the present disclosure. FIG. 1B is an enlarged schematic diagram of the dashed-line frame S1 in FIG. 1A. FIG. 1C is a schematic diagram of the single layer where the gate line is located in FIG. 1A. FIG. 1D is a schematic diagram of the single layer of the active layer in FIG. 1A. FIG. 1E is a schematic diagram of the single layer where the data line is located in FIG. 1A. FIG. 1F is a schematic diagram of the single layer of the first insulating layer in FIG. 1A. FIG. 1G is a schematic diagram of the single layer where the pixel electrode is located in FIG. 1A. FIG. 1H is a schematic diagram of the black matrix layer corresponding to FIG. 1A. FIG. 2A is the second schematic diagram of the array substrate provided by an embodiment of the present disclosure. FIG. 2B is the enlarged schematic diagram of the dashed-line frame S1 in FIG. 1A. FIG. 2C is the schematic diagram of the single layer where the gate line is located in FIG. 2A. FIG. 2D is the schematic diagram of the single layer of the active layer in FIG. 2A. FIG. 2E is the schematic diagram of the single layer where the data line is located in FIG. 2A. FIG. 2F is the schematic diagram of the single layer of the first insulating layer in FIG. 2A. FIG. 2G is the schematic diagram of the single layer of the first conductive layer in FIG. 2A. FIG. 2H is the schematic diagram of the second insulating layer corresponding to FIG. 2A. FIG. 2I is the schematic diagram of the pixel electrode layer corresponding to FIG. 2A. FIG. 2J is the schematic diagram of the black matrix layer corresponding to FIG. 2A. FIG. 3A is the third schematic diagram of the array substrate provided by an embodiment of the present disclosure. FIG. 3B is the enlarged schematic diagram of dashed-line frame S1 in FIG. 3A. FIG. 3C is a schematic diagram of the single layer where the gate line is located in FIG. 3A. FIG. 3D is a schematic diagram of the single layer of the active layer in FIG. 3A. FIG. 3E is the schematic diagram of the single layer where the data line is located in FIG. 3A. FIG. 3F is the schematic diagram of the single layer of the first insulating layer in FIG. 3A. FIG. 3G is the schematic diagram of the single layer of the first conductive layer in FIG. 3A. FIG. 3H is the schematic diagram of the second insulating layer corresponding to FIG. 3A. FIG. 3I is the schematic diagram of the pixel electrode layer corresponding to FIG. 3A. FIG. 3J is the schematic diagram of the black matrix layer corresponding to FIG. 3A. FIG. 4A is the fourth schematic diagram of the array substrate provided by an embodiment of the present disclosure. FIG. 4B is an enlarged schematic diagram of the dashed-line frame S1 in FIG. 4A. FIG. 4C is a schematic diagram of the single layer where the gate line is located in FIG. 4A. FIG. 4D is a schematic diagram of the single layer of the active layer in FIG. 4A. FIG. 4E is a schematic diagram of the single layer where the data line is located in FIG. 4A. FIG. 4F is a schematic diagram of the single layer of the first insulating layer in FIG. 4A. FIG. 4G is a schematic diagram of the single layer of the first conductive layer in FIG. 4A. FIG. 4H is a schematic diagram of the second insulating layer corresponding to FIG. 4A. FIG. 4I is a schematic diagram of the pixel electrode layer corresponding to FIG. 4A. FIG. 4J is a schematic diagram of the black matrix layer corresponding to FIG. 4A. FIG. 5A is the fifth of the schematic diagram of the array substrate provided by an embodiment of the present disclosure. FIG. 5B is an enlarged schematic diagram of the dashed-line frame S1 in FIG. 5A. FIG. 5C is a schematic diagram of the single layer where the gate line is located in FIG. 5A. FIG. 5D is a schematic diagram of a single layer of the active layer in FIG. 5A. FIG. 5E is a schematic diagram of a single layer where the data line is located in FIG. 5A. FIG. 5F is a schematic diagram of a single layer of the first insulating layer in FIG. 5A. FIG. 5G is a schematic diagram of a single layer of the first conductive layer in FIG. 5A. FIG. 5H is a schematic diagram of the second insulating layer corresponding to FIG. 5A. FIG. 5I is a schematic diagram of the pixel electrode layer corresponding to FIG. 5A. FIG. 5J is a schematic diagram of the black matrix layer corresponding to FIG. 5A.

Some embodiments of the present disclosure provide an array substrate, including:
a base substrate 1;
a plurality of gate lines 2 on a side of the base substrate 1, and the plurality of gate lines 2 extending along the first direction X;
a plurality of data lines 3, the main body direction of the plurality of data lines 3 extends along the second direction Y, and the orthographic projection of the data lines 3 on the base substrate 1 is bent in shape. In some embodiments, the second direction Y and the first direction X intersect, or, the second direction Y can be perpendicular to the first direction X. In some embodiments, the second direction Y may be the column direction of the pixel electrode, and the first direction X may be the row direction of the pixel electrode;
a plurality of pixel electrodes 4, the orthographic projection of the pixel electrodes 4 on the base substrate 1 is between the orthographic projections of adjacent data line 3 on the base substrate 1. Each pixel electrode 4 includes a plurality of slits F, and the extension direction of the orthographic projection of the slits F on the base substrate 1 is consistent with the extension direction of the orthographic projections of the adjacent data line 3 on base substrate 1. For example, as shown in FIG. 1A, each pixel electrode 4 includes four sub-electrode portions sequentially distributed along the second direction Y, namely the first sub-electrode portion P1, the second sub-electrode portion P2, the third sub-electrode portion P3, and the fourth sub-electrode portion P4. The extension direction of slits F in the first sub-electrode portion P1 is consistent with the extension direction of the data lines 3 on both sides of the slits F in the first sub-electrode portion P1, the extension direction of slits F in the second sub-electrode portion P2 is consistent with the extension direction of the data lines 3 on both sides of the slits F in the second sub-electrode portion P2, the extension direction of slits F in the third sub-electrode P3 is consistent with the extension direction of the data lines 3 on both sides of the slits F in the third sub-electrode P3, and the extension direction of slits F in the fourth sub-electrode P4 is consistent with the extension direction of the data lines 3 on both sides of the slits F in the fourth sub-electrode P4.

In embodiments of the present disclosure, the orthographic projection of the data lines 3 on the base substrate 1 is bent in shape, and the extension direction of the orthographic projection of the slits F of each pixel electrode 4 on the base substrate 1 is consistent with the extension direction of the orthographic projection of adjacent data line 3 on the base substrate 1, so that the edge electric field of the pixel electrodes 4 and the internal electric field of the pixel electrodes 4 are in the same direction, the liquid crystal disorder phenomenon is reduced or disappears, and the edge dark lines of the pixel electrodes 4 also disappear accordingly. Moreover, the occurrence of liquid crystal molecules in the 90°/270° direction in the area where the pixel electrode 4 is, can be reduced or eliminated, so as to improve the color shift of the viewing angle of the display panel in the first direction X (left and right).

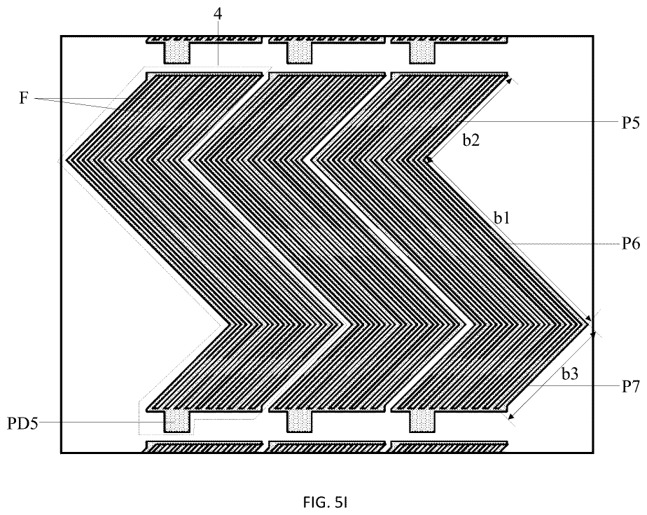

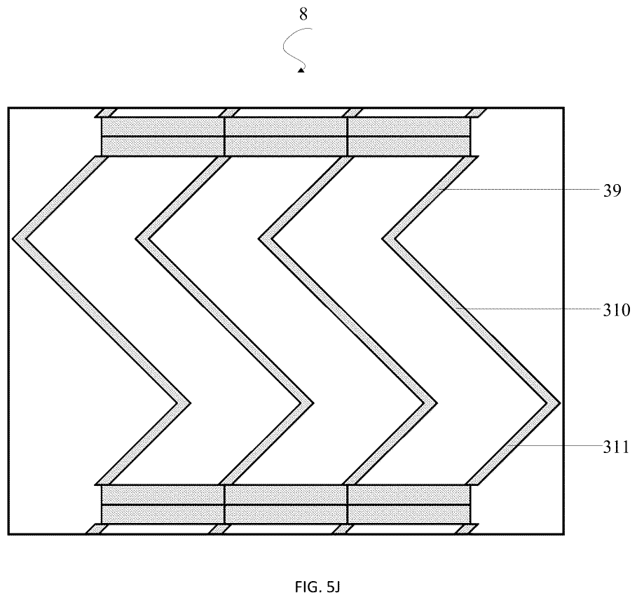

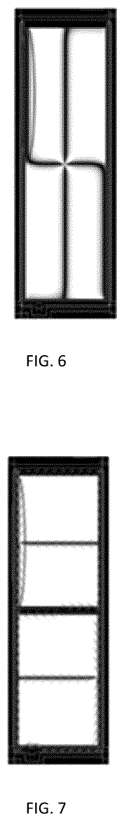

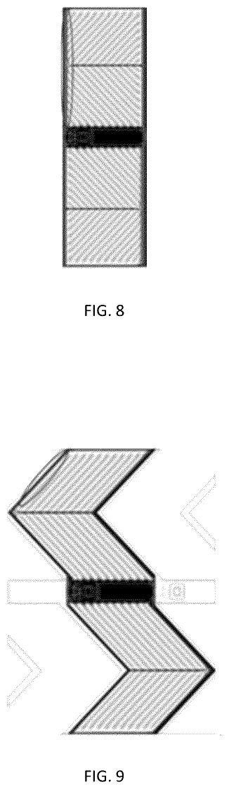

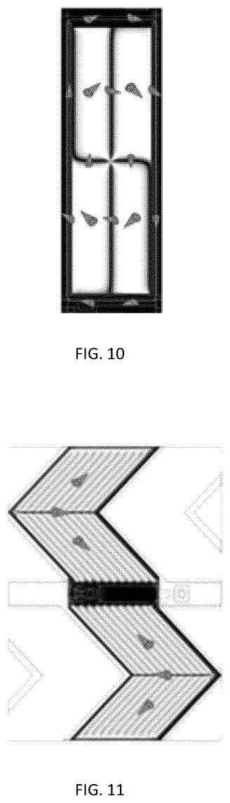

In some embodiments, as shown in FIG. 6 to FIG. 9, FIG. 6 is the simulation diagram of the luminous effect of the display panel of UV2A orientation mode at a sub-pixel. FIG. 7 is the simulation diagram of the luminous effect of the display panel of SUVA orientation mode at a sub-pixel. FIG. 8 is the simulation diagram of luminous effect of the display panel of the SUVA-ADS orientation mode at a sub-pixel when the data line is vertically routed. FIG. 9 is the simulation diagram of the luminous effect of the display panel at a sub-pixel provided by an embodiment of the present disclosure. It can be seen that, in the traditional UV2A orientation mode structure, SUVA orientation mode structure, and SUVA-ADS orientation mode structure, when the data line is in the vertical direction (that is, along the second direction Y), there will be dark lines on the edge of the data lines, that is, because the liquid crystal of the edge electric field is in the horizontal direction (that is, along the first direction X), and the liquid crystal in the sub-pixel is in the direction of 45 degrees, the edge of the data lines will appear in the situation of liquid crystals in different directions. After the data lines are changed to a bending (45°) design, the electric field at the edge and the electric field in the pixel are in the same direction, and the liquid crystal disorder disappears, and the dark lines at the edge also disappear. In addition, the presence of 90°/270° liquid crystal molecules increases the An (the difference between the refractive index of the major and minor axes of the liquid crystal), which has an impact on the color shift of the large viewing angle. As shown in FIG. 10 and FIG. 11, the array substrate structure provided by embodiments of the present disclosure can reduce or eliminate the occurrence of liquid crystal molecules in the 90°/270° direction in the sub-pixels, thereby improving the color shift of the large viewing angles.

It should be noted that the main body direction of the data lines 3 extends along the second direction Y, which can be understood as each data line 3 as a whole extends along the second direction Y, but can be bent when it is specific to the area corresponding to each pixel electrode 4.

In some embodiments, as shown in FIG. 1A to FIG. 1H, FIG. 2A to FIG. 2J, FIG. 4A to FIG. 4J, and FIG. 5A to FIG. 5J, in the same pixel electrode 4, the curved shape of the orthographic projection of the slits F on the base substrate 1 is consistent with the curved shape of the orthographic projection of adjacent data lines 3 on base substrate 1.

In some embodiments, as shown in FIG. 1A to FIG. 1H, FIG. 2A to FIG. 2J, FIG. 3A to FIG. 3J, the orthographic projection of the gate lines 2 on the base substrate 1 passes through the central area of the orthotropic projection of the pixel electrodes 4 on the base substrate 1. Each pixel electrode 4 has a first gap J1 in the area where the gate line 2 is located. Each pixel electrode 4 includes: a first pixel electrode 41 located on a side of the gate line 2, a second pixel electrode 42 on the other side of the gate line 2, and a connecting portion 43 connecting at least part of the first pixel electrode 41 and at least part of the second pixel electrode 42.

In embodiments of the disclosure, the gate line 2 passes through the central area of the pixel electrode 4, that is, each pixel electrode 4 is divided into a first pixel electrode 41 located on one side of the gate line 2 and a second pixel electrode 42 located on the other side of the gate line 2. At least part of the first pixel electrode 41 is electrically connected with at least part of the second pixel electrode 42, two different light-and-dark display effects can be realized in one pixel electrode 4 cooperating with that the liquid crystal orientation direction of different sub-electrodes in the pixel electrode 4, it is beneficial to realize the distribution of 8 domains in one pixel electrode 4. While improving the edge dark lines, increasing the transmittance, and improving the color shift through the bending of the data line 3, the dark lines can be further reduced and the color shift can be improved by realizing multiple domain phases in one pixel electrode 4.

In some embodiments, as shown in FIG. 1A to FIG. 1H, the array substrate further includes: a plurality of transistors T. The pixel electrode 4 is electrically connected with the data line 3 by the plurality of transistors T. The first pixel electrode 41 includes: a first sub-pixel electrode 411, and a second sub-pixel electrode 412, which are distributed along the first direction X. The second pixel electrode 42 includes: a third sub-pixel electrode 421, and a fourth sub-pixel electrode 422, which are distributed along the first direction X. The second sub-pixel electrode 412 is on a side away from the electrically connected data line 3, of the first sub-pixel electrode 411, and the fourth sub-pixel electrode 422 is on a side away from the electrically connected data line 3, of the third sub-pixel electrode 421. One of the first sub-pixel electrode 411 and the second sub-pixel electrode 412 is electrically connected with one of the third sub-pixel electrode 421 and the fourth sub-pixel electrode 422 through a connecting portion 43. The brightness of the two that are electrically connected with each other is different from the brightness of the other two. For example, the first sub-pixel electrode 411 may be electrically connected with the third sub-pixel electrode 421, and the second sub-pixel electrode 412 is electrically connected with the fourth sub-pixel electrode 422. Alternatively, the first sub-pixel electrode 411 may be electrically connected with the fourth sub-pixel electrode 422, and the second sub-pixel electrode 412 may be electrically connected with the third sub-pixel electrode 421.

In embodiments of the disclosure, one of the first sub-pixel electrode 411 and the second sub-pixel electrode 412 is electrically connected with one of the third sub-pixel electrode 421 and the fourth sub-pixel electrode 422 through a connecting portion 43. The brightness of the two which are electrically connected with each other, is different from the brightness of the other two, so as to realize two kinds of different display effects of light and dark in one pixel electrode 4, cooperating with the liquid crystal orientation direction of different sub-electrodes in the pixel electrode 4, can realize 8 domain distribution in one pixel electrode 4, improve the edge dark lines through the bending of the data line 3, increase the transmittance, and improve the color shift at the same time. For the four parts of the pixel electrode 4, two by two cross electrical connection, so that it is possible to further reduce dark lines and improve color shift by realizing multiple domains in one pixel electrode 4.

It should be noted that in embodiments of the present disclosure, one of the first sub-pixel electrode 411 and the second sub-pixel electrode 412 is electrically connected with one of the third sub-pixel electrode 421 and the fourth sub-pixel electrode 422, which may be one of the first sub-pixel electrode 411 and the second sub-pixel electrode 412 electrically connecting with one of the third sub-pixel electrode 421 and the fourth sub-pixel electrodes 422 in the layer where the pixel electrode 4 is located, and for the other two, may not be connected in the layer where the pixel electrode 4 is located, but can be electrically connected by other structures, for example, the other two are connected with the same transistor drain. For example, the first sub-pixel electrode 411 and the third sub-pixel electrode 421 are electrically connected in the layer where the pixel electrode 4 is located, and they present a brightness, while the second sub-pixel electrode 412 and the fourth sub-pixel electrode 422 are not electrically connected in the layer where the pixel electrode 4 is located, but they can be connected with the same transistor drain to realize another brightness. The brightness of the two sub-pixel electrodes connected in the layer where the pixel electrode 4 is located can be different from the brightness of the other two sub-pixel electrodes.

It is understandable that the brightness of the two sub-pixel electrodes that are electrically connected integrally, being different from the brightness of the other sub-pixel electrodes, refers to the comparison of the brightness within a sub-pixel when the display panel is powered on.

In some embodiments, as shown in FIG. 1A to FIG. 1H, the first sub-pixel electrode 411 and the fourth sub-pixel electrode 422 are electrically connected through a connecting portion 43 at the layer where the pixel electrode 4 is located, and the second sub-pixel electrode 412 is independent from the third sub-pixel electrode 421 at the layer where the pixel electrode 4 is located.

In some embodiments, as shown in FIG. 1A to FIG. 1H, the transistors electrically connected with the same pixel electrode 4 are electrically connected with the same data line 3 and the same gate line 2. For example, as shown in FIG. 1B, there are three transistors electrically connected with the same pixel electrode 4, respectively a first transistor T1, a second transistor T2, and a third transistor T3, which are electrically connected with the same data line 3 and the same gate line 2.

It should be noted that a plurality of transistors electrically connected with the same pixel electrode 4 may refer to being electrically connected with the same pixel electrode 4 by direct or indirect means. For example, the first transistor T1 and the second transistor T2 can be directly electrically connected with the pixel electrode 4, and the third transistor T3 can also be electrically connected with the pixel electrode 4 because it is electrically connected with the second transistor T2. In some embodiments, a plurality of transistors electrically connected with the same pixel electrode 4 may also be individual transistors that drive the same pixel electrode 4 to emit light.

In some embodiments, as shown in FIG. 1A to FIG. 1H, the array substrate further includes: a first common wire 21 on a side of the gate line 2 and extending along the first direction X. The plurality of transistors T includes: a first transistor T1, a second transistor T2, and a third transistor T3.

The control electrode TA of the first transistor T1 is electrically connected with the gate line 2, the first electrode TB of the first transistor T1 is electrically connected with the data line 3, and the second electrode TC of the first transistor T1 is electrically connected with the connecting part 43. In some embodiments, the second electrode TC of the first transistor T1 can be electrically connected with the first sub-pixel electrode 411 and the fourth sub-pixel electrode 422 through the first through hole K1.

The control electrode TA of the second transistor T2 is electrically connected with the gate line 2, the first electrode TB of the second transistor T2 is electrically connected with the data line 3, and the second electrode TC of the second transistor T2 is electrically connected with the second sub-pixel electrode 412 and the third sub-pixel electrode 421. In some embodiments, the second electrode TC of the second transistor T2 can be electrically connected with the third sub-pixel electrode 421 through the second through hole K2; the second electrode TC of the second transistor T2 can be electrically connected with the second sub-pixel electrode 412 through the third through hole K3.

The control electrode TA of the third transistor T3 is electrically connected with the gate line 2, the second electrode TC of the second transistor T2 is multiplexed as the first electrode TB of the third transistor T3, and the second electrode TC of the third transistor T3 is electrically connected with the first common wire 21. In some embodiments, the second electrode TC of the third transistor T3 can be electrically connected with the first common wire 21 through the fourth through hole K4.

In embodiments of the present disclosure, because the third transistor T3 is connected with the second transistor T2, the voltage loaded in the second sub-pixel electrode 412 and the third sub-pixel electrode 421 may be distributed to the first common wire 21 through the third transistor T3, so that the voltage obtained by the second sub-pixel electrode 412 and the third sub-pixel electrode 421 is lower than the voltage obtained by the first sub-pixel electrode 411 and the fourth sub-pixel electrode 422. Furthermore, the luminous brightness of the second sub-pixel electrode 412 and the third sub-pixel electrode 421 is smaller than that of the first sub-pixel electrode 411 and the fourth sub-pixel electrode 422, and then the display effect of different brightness and darkness is formed in the sub-pixel.

In some embodiments, as shown in FIG. 1A to FIG. 1H, the second electrode TC of the first transistor T1 includes: the first portion T1C1 of the first transistor extending along the first direction X. The array substrate further includes: a first lap portion PD1 connected with the connecting portion 43. The orthographic projection of the first lap portion PD1 on the base substrate 1 and the orthographic projection of the first portion T1C1 of the first transistor on the base substrate 1 have an overlapping area. In this way, the first portion T1C1 of the first transistor and the first lap portion PD1 are electrically connected through the first through hole K1 in the overlapping area.

In some embodiments, as shown in FIG. 1A to FIG. 1H, the second electrode TC of the first transistor T1 includes: a second portion T1C2 of the first transistor extending along the second direction Y and electrically connected with the first portion T1C1 of the first transistor. In some embodiments, the orthotropic projection of the second portion T1C2 of the first transistor on base substrate 1 and the orthographic projection of active pattern 5 on base substrate 1 can have an overlapping area.

In some embodiments, as shown in FIG. 1A to FIG. 1H, the connecting portion 43 includes: a first connecting portion 431 extending along the first direction X, a second connecting portion 432 extending along the first direction X, and a third connecting portion 433 extending along the second direction Y.

One end of the first connecting portion 431 is electrically connected with the first sub-pixel electrode 411, and the other end of the first connecting portion 431 is electrically connected with one end of the third connecting portion 433. The other end of the third connecting portion 433 is electrically connected with one end of the second connecting portion 432; the other end of the second connecting portion 432 is electrically connected with the fourth sub-pixel electrode 422.

The first lap portion PD1 is electrically connected with a side away from the first sub-pixel electrode 411, of the first connecting portion 431.

In embodiments of the present disclosure, the connecting portion 43 includes: a first connecting portion 431 extending along the first direction X, a second connecting portion 432 extending along the first direction X, and a third connecting portion 433 extending along the second direction Y. The wiring of the connecting portion 43 is regular, which is conducive to the concise wiring between the gap between the first pixel electrode 41 and the second pixel electrode 42, and avoids that when the layout of multiple patterns is complex, the risk of short circuit is easy to occur when etching patterning. Moreover, the connecting portion 43 is also connected with a first lap portion PD1, so that the first lap portion PD1 and the second electrode TC of the first transistor T1 are electrically connected through the first through hole K1.

In some embodiments, as shown in FIG. 1A to FIG. 1H, there is a second gap J2 between the first connecting portion 431 and the first sub-pixel electrode 411, and a third gap J3 between the second connecting portion 432 and the fourth sub-pixel electrode 422.

In some embodiments, as shown in FIG. 1G, the length a1 of the first lap portion PD1 on the second direction Y is greater than the length a2 of the first connecting portion 431 on the second direction Y. In this way, the first lap part PD1 has sufficient area to be electrically connected with the first portion T1C1 of the first transistor through the first through hole K1.

In some embodiments, as shown in FIG. 1A to FIG. 1H, the second electrode TC of the second transistor T2 includes: the first portion T2C1 of the second transistor extending along the first direction X of the second transistor, and the second portion T2C2 of the second transistor extending from the first portion T2C1 of the second transistor along the second direction Y.

The array substrate further includes: a first adapter PZ1 extending along the first direction X, a second adapter PZ2 extending along the second direction Y, and a second lap portion PD2. One end of the first adapter PZ1 is electrically connected with the second sub-pixel electrode 412, and the other end of the first adapter PZ1 is electrically connected with one end of the second adapter PZ2. The other end of the second adapter PZ2 is electrically connected with the second lap portion PD2. The orthographic projection of the second portion T2C2 of the second transistor on base substrate 1 and the orthographic projection of the second lap portion PD2 on base substrate 1 have an overlapping area. In this way, the second lap portion PD2 and the second portion T2C2 of the second transistor are electrically connected through the third through hole K3 at the overlapping area.

The array substrate further includes: a third adapter PZ3 along the first direction X and a third lap connecting portion PD3. One end of the third adapter PZ3 is electrically connected with the third sub-pixel electrode 421, and the other end of the third adapter PZ3 is electrically connected with the third lap portion PD3. The orthographic projection of the first portion T2C1 of the second transistor on base substrate 1 and the orthographic projection of the third lap portion PD3 on base substrate 1 have an overlapping area. In this way, the third lap portion PD3 and the first portion T2C1 of the second transistor are electrically connected through the second through hole K2 at the overlapping area.

In embodiments of the disclosure, one side of the second sub-pixel electrode 412 is further provided with a first adapter PZ1, a second adapter PZ2 extending along the second direction Y, and a second lap portion PD2, so that the second sub-pixel electrode 412 is electrically connected with the second electrode TB of the second transistor T2, and the wiring mode of electrically connecting the second sub-pixel electrode 412 with the second electrode TB of the second transistor T2 is simple and regular, and it is conducive to the concise wiring between the gap between the first pixel electrode 41 and the second pixel electrode 42, and avoids the risk of short circuit when the layout of multiple patterns is complex, and the risk of short circuit is easy to occur when etching patterning.

In some embodiments, as shown in FIG. 1G, the second electrode TC of the second transistor T2 may also include: a third portion T2C3 of the second transistor that is electrically connected with the other end of the first portion T2C1 of the second transistor and extends along the second direction Y. In some embodiments, the orthographic projection of the third portion T2C3 of the second transistor on the base substrate 1 and the orthographic projection of the active pattern 6 on the base substrate 1 may have an overlapping area.

In some embodiments, as shown in FIG. 1G, there is a fourth gap J4 between the first adapter PZ1 and the second sub-pixel electrode 412, and a fifth gap J5 between the third adapter PZ3 and the third sub-pixel electrode 421.

In some embodiments, as shown in FIG. 1G, the length a3 of the second lap portion PD2 on the first direction X is greater than the length a4 of the second adapter PZ2 on the first direction X, so that the second lap portion PD2 has sufficient area to electrically connect with the second portion T2C2 of the second transistor through the third through hole K3. The length a5 of the third lap portion PD3 on the second direction Y is greater than the length a6 of the third adapter PZ3 on the second direction Y, so that the third lap portion PD3 has sufficient area to be electrically connected with the first portion T2D1 of the second transistor through the second through hole K2.

In some embodiments, as shown in FIG. 1A to FIG. 11, the second electrode TC of the third transistor T3 includes: the first portion T3C1 of the third transistor extending along the second direction Y, and the second portion T3C2 of the third transistor extending from the first portion T3C1 of the third transistor along the first direction X.

The array substrate further includes: a fourth lap portion PD4. The first common wiring 21 includes: a main portion of the first common wiring 211 and a first common lap portion 212 connected with one side of the main portion of the first common wiring 211.

The orthographic projection of the first common lap portion 212 on the base substrate 1 and the orthographic projection of the fourth lap portion PD4 on the base substrate 1 have an overlapping area. In this way, the first common lap part 212 and the second portion T3C2 of the third transistor are conducted in the overlapping area through the fourth through hole K4. The orthographic projection of the second portion T3C2 of the third transistor on the base substrate 1 and the orthographic projection of the fourth lap portion PD4 on the base substrate 1 have an overlapping area, so that the fourth lap portion PD4 and the second portion T3C2 of the third transistor are conducted in the overlapping area through the fourth through hole K4.

In some embodiments, as shown in FIG. 11, FIG. 1I can be a cross-sectional schematic diagram along the dashed line EF in FIG. 1B. The fourth through hole K4 can be designed as a semi-hole, the fourth through hole K4 partially exposes the first common wire 21, partially exposes the second electrode TC of the third transistor T3. The fourth lap portion PD4 partially contacts with the first common wire 21 at the fourth through hole K4, and partially contacts with the second electrode TC of the third transistor T3, to realize that the first common wire 21 is electrically connected with the second portion T3C2 of the third transistor through the fourth lap portion PD4. In some embodiments, the design of the fourth through hole K4 is a semi-hole, which can make the fourth through hole K4 form a step structure inside, play a drainage role on the orientation liquid, and avoid the technical effect of moire pattern phenomenon in the picture.

In some embodiments, as shown in FIG. 1E, the extension direction of the first portion T3C1 of the third transistor is parallel to the extension direction of the second portion T2C2 of the second transistor.

In some embodiments, as shown in FIG. 1E, where the extension direction of at least part of the first portion T1C1 of the first transistor is parallel to the extension direction of at least part of the first portion T2C1 of the second transistor. In this way, it is conducive to the concise wiring between the gap between the first pixel electrode 41 and the second pixel electrode 42, and avoids the risk of short circuit defect when the pattern layout of multiple patterns is complex, and the etching pattern is prone to occur.

In some embodiments, as shown in FIG. 1G, the fourth lap portion PD4 has a fourth lap portion outer edge f1 along the first direction X, and the second lap portion PD2 has a second lap portion outer edge f2 extending along the first direction X. The extension line of the fourth lap portion outer edge f1 coincides with the extension line of the second lap portion outer edge f2, so that the pattern distribution between the gap between the first pixel electrode 41 and the second pixel electrode 42 is simple and regular, and the risk of short circuit is easy to occur when the layout of multiple patterns is complex.

In some embodiments, as shown in FIG. 1G, the first lap portion PD1 has a first lap portion outer edge f3 extending along the second direction Y, and the third lap portion PD3 has a third lap portion outer edge f4 extending along the second direction Y. The extension line of the first lap portion outer edge f3 coincides with the extension line of the third lap portion outer edge f4, so that the pattern distribution between the gap between the first pixel electrode 41 and the second pixel electrode 42 is concise and regular, and the risk of short circuit is easy to occur when the layout of multiple patterns is complex, and the risk of short circuit is easy to occur when etching patterning is avoided.

In some embodiments, as shown in FIG. 1A to FIG. 1H, the array substrate further includes: a second common wiring group 22 that is electrically connected with the first common wire 21 and extends to a side away from the gate line 2. The second common wiring group 22 includes: two second common wire 220. The orthographic projection of the data line 3 on the base substrate 1 and the orthographic projection of a gap between the two second common wires 220 of the same second common wiring group 22 have an overlapping area on the base substrate 1. The shape of the orthographic projection of the second common wires 220 on base substrate 1 is curved, and the curved shape of the orthographic projection of the second common wires 220 on base substrate 1 is consistent with the curved shape of the orthographic projection of data line 3 on base substrate 1. In embodiments of the present disclosure, the curved shape of the second common wires 220 being consistent with the curved shape of the data line 3, can match the curved of the data line 3, and the orthographic projections of the second common wires 220 on the base substrate 1 are located on both sides of the orthographic projection of the data line 3 on the base substrate 1, and the coupling capacitance between the data line 3 and the second pixel electrode 42 can be improved.

In some embodiments, as shown in FIG. 1A to FIG. 1H, the array substrate further includes: a third common wire 23 located on the opposite side of the gate line 2 and extending along the first direction X, and a fourth common wiring group 24 connected with the third common wire 23 and extending to a side away from the gate line 2. The third common wire 23 is disconnected at the position where it intersects with the data line 3, so as to avoid the load of the data line 3 increasing, and the signal transmission of the data line 3 being affected due to the third common wire 23 and the data line 3 overlapping. The fourth common wiring group 24 includes: two fourth common wires 240. The orthographic projection of the data line 3 on the base substrate 1 and the orthographic projection of a gap between the two fourth common wires 240 of the same fourth common wiring group 24 have an overlapping area on the base substrate 1. The shape of the orthographic projection of the fourth common wires 240 on the base substrate 1 is curved, and the curved shape of the orthographic projection of the fourth common wires 240 on the base substrate 1 is consistent with the curved shape of the orthographic projection of the data line 3 on the base substrate 1. In embodiments of the disclosure, the curved shape of the fourth common wires 240 being consistent with the curved shape of the data line 3, can match the curved shape of the data line 3, and the orthographic projection of the fourth common wires 240 on the base substrate 1 are located on both sides of the orthographic projection of the data line 3 on the base substrate 1, and the coupling capacitance between the data line 3 and the first pixel electrode 41 can be improved.

In some embodiments, as shown in FIG. 2A to FIG. 2, the first pixel electrode 41 is an integral structure, and the second pixel electrode 42 is an integral structure. That is, as shown in FIG. 2I, the first pixel electrode 41 on one side of the gate line 2 no longer splits in the left and right directions, and the second pixel electrode 42 on the other side of the gate line 2 no longer splits the left and right directions, so that the production of the pixel electrode 4 is simplified, and the risk of short circuit defect occurring on the array substrate is reduced due to the complex pattern of the pixel electrode 4.

In some embodiments, as shown in FIG. 2I, one end away from gate line 2, of the first pixel electrode 41 is an opening. One end away from gate line 2, of the second pixel electrode 42 is an opening. In embodiments of the disclosure, one end away from gate line 2, of the first pixel electrode 41 is an opening, and one end away from gate line 2, of the second pixel electrode 42 is an opening, which can reduce the dark lines of the sub-pixel at the edge of the pixel electrode 4, and improve the transmittance of the display panel.

It should be noted that when the first pixel electrode 41 and the second pixel electrode 42 have a plurality of branch electrodes and have the slit F between adjacent branch electrodes, one end away from gate line 2, of the first pixel electrode 41 is an opening, and one end away from gate line 2, of the second pixel electrode 42 is an opening, which can be understood as the ends of the branch electrodes are not connected with each other, and the ends of the slits F are not connected with each other.

In some embodiments, as shown in FIG. 2I, the shape of the orthographic projection of the connecting portion 43 on base substrate 1 is rectangular. In this way, the production of pixel electrode 4 is simplified, and the risk of short circuit defect occurs on the array substrate due to the complex pattern of pixel electrode 4 is reduced.

In some embodiments, as shown in FIG. 2I, the connecting portion 43 is a block electrode. In some embodiments, as shown in FIG. 2I, the connecting portion 43 may include: the first side edge f5 extending along the second direction Y, and the second side edge f6 extending along the second direction Y.

In some embodiments, as shown in FIG. 2A-FIG. 2J, the gate line 2 has a gate-line hollow 20. The orthographic projection of the gate-line hollow 20 on the base substrate 1 covers at least a part of the orthographic projection of the connecting portion 43 on the base substrate 1. In embodiments of the present disclosure, the gate line 2 has the gate-line hollow 20, the orthographic projection of the gate-line hollow 20 on the base substrate 1 covers at least a part of the orthographic projection of the connecting portion 43 on the base substrate 1, so that the pixel electrode 4 and the gate line 2 can be avoided from producing an overlapping area at the connecting portion 43, causing the pixel electrode 4 and the gate line 2 to produce a coupling capacitance, thereby increasing the load of the gate line 2 and affecting the signal transmission of the gate line 2.

In some embodiments, as shown in FIG. 2A to FIG. 2J, the orthographic projection of the gate-line hollow 20 on the base substrate 1 can cover the entire orthographic projection of the connecting portion 43 on the base substrate 1. In some embodiments, the orthographic projection of the gate-line hollow 20 on the base substrate 1 may also cover only the part of the orthographic projection of the connecting portion 43 on the base substrate 1.

In some embodiments, as shown in FIG. 2A to FIG. 2J, the array substrate may be provided with only one fourth transistor T4 at each pixel electrode 4, and the fourth transistor T4 may include: a gate TA, an active pattern 5, a first electrode TB, and a second electrode TC. The gate line 2 can be multiplexed as the gate TA. The data line 2 can be multiplexed as the first electrode TB. The second electrode TC may include: the first portion T4C1 of the fourth transistor, the second portion T4C2 of the fourth transistor, and the third portion T4C3 of the fourth transistor distributed in sequence along the first direction X. The orthographic projection of the third portion T4C3 of the fourth transistor on the base substrate 1 and the orthographic projection of the connecting portion 43 on the base substrate 1 have an overlapping area, so that the connecting portion 43 is electrically connected with the third portion T4C3 of the fourth transistor through the first-insulating-layer though hole 910 passing through the first insulating layer 91 and the second-insulating-layer through hole 920 passing through the second insulating layer 92, so as to further realize the electrical connection between the pixel electrode 4 and the fourth transistor T4.

In some embodiments, as shown in FIG. 1A to FIG. 1H, FIG. 2A to FIG. 2J, the first pixel electrode 41 includes: a first sub-electrode portion P1 distributed along the second direction Y, and a second sub-electrode portion P2 distributed along the second direction Y. The extension direction of the first sub-electrode portion P1 is different from that of the second sub-electrode portion P2. The second pixel electrode 42 includes: a third sub-electrode portion P3 distributed along the second direction Y, and the fourth sub-electrode portion P4 distributed along the second direction Y. The extension direction of the third sub-electrode P3 is different from that of the fourth sub-electrode P4. In this way, the pixel electrode 4 is matched with the curved shape of the data line 3, so that the edge electric field direction of the pixel electrode 4 is identical to the internal electric field direction of the pixel electrode 4, the liquid crystal disorder phenomenon is reduced or eliminated, the edge dark lines of the pixel electrode 4 is improved, and the color shift of the left-right view angles of the display panel is improved.

In some embodiments, the first pixel electrode 41 is an integrated structure, and the second pixel electrode 42 is an integrated structure. As shown in FIG. 2I, the first pixel electrode 41 may include: a first sub-electrode portion P1 distributed along the second direction Y, and a second sub-electrode portion P2 distributed along the second direction Y, and the second pixel electrode 42 includes: a third sub-electrode portion P3 distributed along the second direction Y, and a fourth sub-electrode portion P4 distributed along the second direction Y. In response to the first pixel electrode 41 further including: a first sub-pixel electrode 411 and a second sub-pixel electrode 412 sequentially distributed along the first direction X, the second pixel electrode 42 further including: a third sub-pixel electrode 421 and a fourth sub-pixel electrode 422 sequentially distributed along the first direction X, both of the first sub-pixel electrode 411 and the second sub-pixel electrode 412 include: a first sub-electrode portion P1 distributed along the second direction Y and a second sub-electrode portion P2 distributed along the second direction Y, and both of the third sub-pixel electrode 421 and the fourth sub-pixel electrode 422 include: a third sub-electrode portion P3 distributed along the second direction Y and a fourth sub-electrode portion P4 distributed along the second direction Y.

In some embodiments, as shown in FIG. 1A to FIG. 1H, the extension direction of the first sub-electrode portion P1 is the same as that of the fourth sub-electrode portion P4. The extension direction of the second sub-electrode portion P2 is the same as that of the third sub-electrode portion P3. In some embodiments, for example, as shown in FIG. 1A to FIG. 1H, the angle between the extension direction of the first sub-electrode portion P1 and the first direction X can be 40°~50°. For example, it may be 45°. The angle between the extension direction of the second sub-electrode portion P2 and the first direction X may be 130°~140°. For example, it may be 135°. The angle between the extension direction of the third sub-electrode portion P3 and the first direction X may be 130°~140°. For example, it may be 135°. The angle between the extension direction of the fourth sub-electrode portion P4 and the first direction X may be 40°~50°. For example, it may be 45°.

In some embodiments, as shown in FIG. 2A to FIG. 2J, the extension direction of the first sub-electrode portion P1 is the same as that of the third sub-electrode portion P3. The extension direction of the second sub-electrode portion P2 is the same as that of the fourth sub-electrode portion P4. In some embodiments, for example, as shown in FIG. 1A to FIG. 1H, the angle between the extension direction of the first sub-electrode portion P1 and the first direction X may be 40 50°. For example, it may be 45°. The angle between the extension direction of the second sub-electrode portion P2 and the first direction X may be 130°~140°. For example, it may be 135°. The angle between the extension direction of the third sub-electrode portion P3 and the first direction X can be 40°~50°. For example, it may be 45°. The angle between the extension direction of the fourth sub-electrode portion P4 and the first direction X may be 130°~140°. For example, it may be 135°.

In some embodiments, as shown in FIG. 1A to FIG. 1H, FIG. 2A to FIG. 2J, the extension direction of the slit F in the first sub-electrode portion P1 is the same as that of the first sub-electrode portion P1. The extension direction of the slit F in the second sub-electrode portion P2 is the same as that of the second sub-electrode portion P2. The extension direction of the slit F in the third sub-electrode portion P3 is the same as that of the third sub-electrode portion P3. The extension direction of the slit F in the fourth sub-electrode portion P4 is the same as that of the fourth sub-electrode portion P4. In this way, the direction of the edge electric field of the pixel electrode 4 is identical to the direction of the internal electric field of the pixel electrode 4, the liquid crystal disorder phenomenon is reduced or eliminated, the edge dark lines of the pixel electrode 4 are improved, and the color shift of left-right view angle of the display panel is improved.

In some embodiments, the length of slit F in a direction perpendicular to the extension direction of the slit F may range from 2 μm to 4 μm. In some embodiments, the length of slit F may be 3 μm in the direction perpendicular to the extension direction of the slit F. In embodiments of the present disclosure, in the array substrate provided based on the embodiment of the present disclosure, when the length of the slit F is reduced to 3 μm in a direction perpendicular to the extension direction of the slit F, the dark lines almost disappears.

In some embodiments, as shown in FIG. 1A to FIG. 1H, the angle between the extension direction of the slit F of the first sub-electrode portion P1 and the first direction X may range from 40° to 50°. For example, it may be 45°. The angle between the extension direction of the slit F of the second sub-electrode portion P2 and the first direction X may range from 130° to 140°. For example, it may be 135°. The angle between the extension direction of slit F of the third sub-electrode portion P3 and the first direction X may range from 130° to 140°. For example, it may be 135°. The angle between the extension direction of the slit F of the fourth sub-electrode portion P4 and the first direction X may range from 40° to 50°. For example, it may be 45°.

In some embodiments, the angle between the orientation direction of the liquid crystal in the area where the first sub-electrode portion P1 is located and the first direction X may range from 220° to 230°. For example, it may be 225°. The angle between the orientation direction of the liquid crystal in the area where the second sub-electrode portion P2 is located and the first direction X may range from 130° to 140°. For example, it may be 135. The angle between the orientation direction of the liquid crystal in the area where the third sub-electrode portion P3 is located and the first direction X may range from 310° to 320°. For example, it may be 315°. The angle between the orientation direction of the liquid crystal in the area where the fourth sub-electrode portion P4 is located and the first direction X may range from 40° to 50°. For example, it may be 45°. By realizing that the area where a pixel electrode 4 is located, includes four orientation directions together with the segmented light and dark areas, the orientation mode of 8 domains in a sub-pixel can be formed when using the Super UV Photo Alignment, SUVA technology.

In some embodiments, as shown in FIG. 1A to FIG. 1H, FIG. 2A to FIG. 2J, the data line 3 includes: a first data portion 31 located on a side of the first sub-electrode portion P1 and having an extension direction same as the extension direction of the first sub-electrode portion P1, a second data portion 32 located on a side of the second sub-electrode portion P2 and having an extension direction same as the extension direction of the second sub-electrode portion P2, a third data portion 33 located on a side of the third sub-electrode portion P3 and having an extension direction same as the extension direction of the third sub-electrode portion P3, and a fourth data portion 34 located on a side of the fourth sub-electrode portion P4, and having an extension direction same as the extension direction of fourth sub-electrode portion P4. In this way, the curved shape of the data line 3 is consistent with the curved shape of the pixel electrode 4, so that the direction of the edge electric field of the pixel electrode 4 is identical to the direction of the internal electric field of the pixel electrode 4, the liquid crystal disorder phenomenon is reduced or eliminated, the edge dark lines of the pixel electrode 4 is improved, and the color shift of the left-right view angles of the display panel is improved.

In some embodiments, as shown in FIG. 1A to FIG. 1H, FIG. 2A to FIG. 2J, the data line 3 further includes: a fifth data portion 35 extending along the second direction Y and connecting the second data portion 32 and the third data portion 33. In this way, it matches with the design of gate line passing through the central area of the pixel electrode 4, so that the transistor is conveniently arranged at the area where the fifth data portion 35 is located.

In some embodiments, as shown in FIG. 3A to FIG. 3J, the first pixel electrode 41 and the second pixel electrode 42 both extend along the third direction Z, and the outer edge of the first pixel electrode 41 along the extension direction does not coincide with the outer edge of the second pixel electrode 42 along the extension direction. In embodiments of the disclosure, the pixel electrode 4 only includes the first pixel electrode 41 and the second pixel electrode 42 extending along the third direction Z, so as to simplify the fabrication of the pixel electrode 4 and reduce the risk of short circuit occurs in the array substrate due to the complex pattern of the pixel electrode 4.

In some embodiments, the angle between the third direction Z and the first direction X ranges from 0° to 90°. In some embodiments, the angle between the third direction Z and the first direction X ranges from 40° to 50°. For example, it may be 45°.

In some embodiments, as shown in FIG. 3A to FIG. 3J, the data line 3 includes: a sixth data portion 36 on a side of the first pixel electrode 41, and a seventh data portion 37 on a side of the second pixel electrode 42. The extension direction of the sixth data portion 36 is the same as that of the seventh data portion 37, and the extension line of the sixth data section 36 does not coincide with the extension line of the seventh data section 37. In this way, the curved shape of the data line 3 is consistent with the curved shape of the pixel electrode 4, so that the direction of the edge electric field of the pixel electrode 4 is identical to the direction of the internal electric field of the pixel electrode 4, the liquid crystal disorder phenomenon is reduced or eliminated, the edge dark lines of the pixel electrode 4 is improved, and the color shift of the left-right view angles of the display panel is improved.

In some embodiments, as shown in FIG. 3A to FIG. 3J, the data line 3 further includes: an eighth data portion 38 extending along the second direction Y and connecting the sixth data section 36 and the seventh data section 37. In this way, it matches with the design of the gate line 2 passing through the central area of the pixel electrode 4, so that the transistor can be arranged at the area where the eighth data section 38 is located.

In some embodiments, as shown in FIG. 3A to FIG. 3J, the array substrate may be provided with only one fourth transistor T4 at each pixel electrode 4. The fourth transistor T4 may include: a gate TA, an active pattern 5, a first electrode TB, and a second electrode TC. The gate line 2 may be multiplexed as the gate TA, the data line 2 may be multiplexed as the first electrode TB, and the second electrode TC may include: the first portion T4C1 of the fourth transistor, the second portion T4C2 of the fourth transistor, and the third portion T4C3 of the fourth transistor distributed in sequence along the first direction X. The orthographic projection of the third portion T4C3 of the fourth transistor on the base substrate 1 and the orthographic projection of the connecting portion 43 on the base substrate 1 have an overlapping area, so that the connecting portion 43 is electrically connected with the third portion T4C3 of the fourth transistor through the first-insulating-layer through hole 910 passing through the first insulating layer 91 and the second-insulating-layer through hole 920 passing through the second insulating layer 92, so as to further realize the electrical connection between the pixel electrode 4 and the fourth transistor T4.

In some embodiments, as shown in FIG. 2A to FIG. 2J and FIG. 3A to FIG. 3J, the first conductive layer 7 further includes a conductive-layer hollow 70. The non-hollow portion of the first conductive layer 7 includes a block electrode. In the area of the block electrode and the pixel electrode, the orthographic projection of the conductive-layer hollow 70 on the base substrate 1, and the orthographic projection of the connecting portion 43 on the base substrate 1 have an overlapping area, so that the connecting portion 43 is also electrically connected with the second portion T5C2 of the fifth transistor through the conductive-layer hollow 70, and the electrical connection between the pixel electrode 4 and the fifth transistor T5 is further realized.

In some embodiments, as shown in FIG. 4A to FIG. 4J, FIG. 5A to FIG. 5J, the orthographic projection of gate line 2 on base substrate 1 is located on a side of the orthographic projection of the pixel electrode 4 on the base substrate 1. That is, In embodiments of the present disclosure, the gate line 2 may also be located on one side of the pixel electrode 4 without passing through the central area of the pixel electrode 4.

In some embodiments, as shown in FIG. 2A to FIG. 2J, FIG. 3A to FIG. 3J, FIG. 4A to FIG. 4J, and FIG. 5A to FIG. 5J, the array substrate further includes: a first conductive layer 7 on a side facing the base substrate 1, of the pixel electrode 4. In embodiments of the disclosure, for a display panel with a pixel electrode layer on the array substrate and a VA display mode of a common electrode layer on the opposite substrate, a first conductive layer 7 is also arranged on a side facing the base substrate 1, of the pixel electrode 4, and in addition to the vertical electric field formed by the pixel electrode and the common electrode in the array substrate, the pixel electrode 4 and the first conductive layer 7 form a transverse electric field, which can increase the deflection direction of the liquid crystal and improve the color shift problem of the display panel.

In some embodiments, for the array substrate structure shown in FIG. 1A, a first conductive layer 7 can also be arranged between the layer where the data line 3 is located and the layer where the pixel electrode 4 is located, so that in addition to the vertical electric field formed by the pixel electrode and the common electrode in the array substrate, the pixel electrode 4 and the first conductive layer 7 can form a transverse electric field, increasing the deflection direction of the liquid crystal, and improving the color shift problem of the display panel.

In some embodiments, the first conductive layer 7 may be located between the layers where the base substrate 1 and the pixel electrode 4 are respectively located. In some embodiments, the first conductive layer 7 may be loaded with signals same as signals loading on the common electrode layer of the opposite substrate. The first conductive layer 7 may be a transparent electrode layer, and the material of the first conductive layer 7 may be indium tin oxide.

In some embodiments, see FIG. 4A to FIG. 4J, FIG. 5A to FIG. 5J, the fifth common line 25 is on a layer same as the layer where the gate line 2 is located. The first conductive layer 7 is electrically connected with the fifth common wire 25 through a conduction hole KD. In embodiments of the present disclosure, because the first conductive layer 7 is of a large-area sheet structure, and the material of the first conductive layer 7 is usually a metal oxide (for example, indium tin oxide), and the material of the fifth common wire 25 is usually metal of the conductivity which is better than the conductivity of the metal oxide, the first conductive layer 7 is electrically connected with the fifth common wire 25, so that the resistance of the first conductive layer 7 can be reduced.

In some embodiments, as shown in FIG. 2A to FIG. 2J, FIG. 3A to FIG. 3J, FIG. 4A to FIG. 4J, FIG. 5A to FIG. 5J, the data line 3 may be located on a side away from the base substrate 1, of the gate line 2, the first conductive layer 7 may be located on a side away from the gate line 2, of the data line 3, the pixel electrode 4 may be located on a side away from the data line 3, of the first conductive layer 7. A gate insulating layer may also be arranged between the layer where the gate line 2 is located and the layer where the data line 3 is located. An active layer may also be arranged between the gate insulating layer and the data line 3 (the active layer may include an active pattern 6, and the material of the active layer may be amorphous silicon, low-temperature polysilicon, metal oxide and other materials, which are not limited here). A first insulating layer 91 may also be arranged between the data line 3 and the first conductive layer 7, and a second insulating layer 92 may be arranged between the first conductive layer 7 and the pixel electrode 4.

In some embodiments, the conduction hole KD may pass through each layer between the fifth common wire 25 and the first conductive layer 7 so as to realize the electrical connection between the first conductive layer 7 and the fifth common wire 25. In some embodiments, the conduction hole KD may pass through the gate insulating layer, the first insulating layer 91, and the second insulating layer 92.

In some embodiments, as shown in FIG. 4A to FIG. 4J, FIG. 5A to FIG. 5J, the fifth common wire 25 has a first common convex portion 251 arranged on a side facing the gate line 2, of the fifth common wire 25. At least parts of orthographic projection of the first common convex portion 251 on the base substrate 1 overlaps at least parts of the orthographic projection of the conduction hole KD on the base substrate 1. In embodiments of the disclosure, the fifth common wire 25 has a first common convex portion 251 arranged on a side facing the gate line 2, of the fifth common wire 25, so that the fifth common wire 25 has a sufficient area to realize the conduction with the first conductive layer 7 through the conduction hole KD.

In some embodiments, as shown in FIG. 4C, and FIG. 5C, the length d1 of the first common convex portion 251 in the second direction Y is greater than the length d2 of the fifth common wire 25 in the second direction Y.

In some embodiments, as shown in FIG. 4C, and FIG. 5C, the gate line 2 has a first notch 201 opposite the first common convex portion 251 on one side facing the fifth common wire 25, of the gate line 2, so as to match the design of the first common convex portion 251 on the fifth common wire 25, avoid the contact between the first common convex portion 251 and the gate line 2.

In some embodiments, as shown in FIG. 4C, and FIG. 5C, one side of the pixel electrode 4 has a fifth lap portion PD5. The gate line 2 has a second notch 202 on the side facing the fifth common wire 25, of the gate line. The orthographic projection of the second notch 202 on base substrate 1 covers the orthographic projection of the fifth lap portion PD5 on base substrate 1, so as to avoid the overlap of the gate line 2 and the fifth lap portion PD5, and avoid occurrence of the coupling capacitance between the gate line 2 and the fifth lap portion PD5, avoid the load of the gate line 2 is increased, and affection of the signal transmission of the gate line 2.

In some embodiments, as shown in FIG. 4C, and FIG. 5C, the array substrate may be provided with only one fifth transistor T5 at each pixel electrode 4, and the fifth transistor T5 may include: a gate TA, an active pattern 5, a first electrode TB, and a second electrode TC. The second electrode TC may include: the first portion T5C1 of the fifth transistor distributed sequentially along the first direction X and the second portion T5C2 of the fifth transistor distributed sequentially along the first direction X. The orthographic projection of the second portion T5C2 of the fifth transistor on the base substrate 1 and the orthographic projection of the fifth lap portion PD5 on the base substrate 1 have an overlapping area, so that the fifth lap portion PD5 is electrically connected with the second portion T5C2 of the fifth transistor through the first-insulating-layer through hole 910 passing through the first insulating 91 and the second-insulating-layer through hole 920 passing through the second insulating layer 92, so as to further realize the electrical connection between the pixel electrode 4 and the fifth transistor T5.

In some embodiments, as shown in FIG. 4A to FIG. 4J and FIG. 5A to FIG. 5J, the first conductive layer 7 further includes a conductive layer hollow 70. The orthographic projection of the conductive layer hollow 70 on the base substrate 1, and the orthographic projection of the fifth lap portion PD5 on the base substrate 1 have an overlapping area, so that the fifth lap portion PD5 is also electrically connected with the second portion T5C2 of the fifth transistor through the conductive layer hollow 70, and the electrical connection between the pixel electrode 4 and the fifth transistor T5 is further realized.

In some embodiments, as shown in FIG. 4A to FIG. 4J, the pixel electrode 4 includes: a first sub-electrode portion P1, a second sub-electrode portion P2, a third sub-electrode portion P3, and a fourth sub-electrode portion P4 sequentially distributed along the second direction Y. The extension direction of the first sub-electrode portion P1 is different from that of the second sub-electrode portion P2. The extension direction of the third sub-electrode portion is different from that of the fourth sub-electrode portion. In this way, the pixel electrode 4 is matched with the curved shape of the data line 3, so that the direction of the edge electric field of the pixel electrode 4 is identical to the direction of the internal electric field of the pixel electrode 4, the liquid crystal disorder phenomenon is reduced or eliminated, the edge dark lines of the pixel electrode 4 is improved, and the color shift the left-right view angles of the display panel is improved.

In some embodiments, as shown in FIG. 4A to FIG. 4J, the extension direction of the first sub-electrode portion P1 is the same as the extension direction of the third sub-electrode portion P3. The extension direction of the second sub-electrode portion P2 is the same as the extension direction of the fourth sub-electrode portion P4. For example, as shown in FIG. 4A to FIG. 4J, the angle between the extension direction of the first sub-electrode portion P1 and the first direction X may range from 40° to 50°. For example, it may be 45°. The angle between the extension direction of the second sub-electrode portion P2 and the first direction X can range from 130° to 140°. For example, it may be 135°. The angle between the extension direction of the third sub-electrode portion P3 and the first direction X may range from 40° to 50°. For example, it may be 45°. The angle between the extension direction of the fourth sub-electrode portion P4 and the first direction X may range from 130° to 140°. For example, it may be 135°.

As shown in FIG. 4A to FIG. 4J, the extension direction of slits F in the first sub-electrode portion P1 is the same as that of the first sub-electrode portion P1. The extension direction of slits F in the second sub-electrode portion P2 is the same as that of the second sub-electrode portion P2. The extension direction of slits F in the third sub-electrode portion P3 is the same as that of the third sub-electrode portion P3. The extension direction of slits F in the fourth sub-electrode portion P4 is the same as that of the fourth sub-electrode portion P4. In this way, the direction of the edge electric field of the pixel electrode 4 is identical to the direction of the internal electric field of the pixel electrode 4, the liquid crystal disorder phenomenon is reduced or eliminated, the edge dark lines of the pixel electrode 4 are improved, and the color shift of the left-right view angles of the display panel is improved.

In some embodiments, the length of slits F in a direction perpendicular to the extension direction thereof may range from 2 μm to 4 μm. For example, the length of slits F may be 3 μm in the direction perpendicular to the direction of extension thereof. In embodiments of the present disclosure, in the array substrate provided based on the embodiment of the present disclosure, when the length of the slits F is reduced to 3 μm in the direction perpendicular to the extension direction thereof, the dark lines almost disappear.

In some embodiments, as shown in FIG. 4A to FIG. 4J, the angle between the extension direction of the slits F of the first sub-electrode portion P1 and the first direction X may be 40°~50°. For example, it may be 45°. The angle between the extension direction of the slits F of the second sub-electrode portion P2 and the first direction X may be 130°~140°. For example, it may be 135°. The angle between the extension direction of the slits F of the third sub-electrode portion P3 and the first direction X may be 40°~50°. For example, it may be 45°. The angle between the extension direction of the slits F of the fourth sub-electrode portion P4 and the first direction X may be 130°~140°. For example, it may be 135°.

In some embodiments, as shown in FIG. 4A to FIG. 4J, the data line 3 includes: a first data portion 31 located on a side of the first sub-electrode portion P1 and extending in a direction same as the extension direction of the first sub-electrode, a second data portion 32 located on a side of the second sub-electrode portion P2 and extending in a direction same as the extension direction of the second sub-electrode portion P2, a third data portion 33 located on a side of the third sub-electrode portion P3 and extending in a direction same as the extension direction of the third sub-electrode portion P3, and the fourth data section 34 located on a side of the fourth sub-electrode portion P4, and extending in a direction same as the extension direction of the fourth sub-electrode portion P4. The second data portion 32 is directly connected with the third data portion 33. In this way, the curved shape of the data line 3 is consistent with the curved shape of the pixel electrode 4, so that the direction of the edge electric field of the pixel electrode 4 is identical to the direction of the internal electric field of the pixel electrode 4, the liquid crystal disorder phenomenon is reduced or eliminated, the edge dark lines of the pixel electrode 4 is improved, and the color shift of the left-right view angles of the display panel is improved.

In some embodiments, as shown in FIG. 5A to FIG. 5J, the pixel electrode 4 includes: a fifth sub-electrode portion P5, a sixth sub-electrode portion P6, and a seventh sub-electrode portion P7 sequentially distributed along the second direction Y. The extension direction of the fifth sub-electrode portion P5 is the same as that of the seventh sub-electrode portion P7. The extension direction of the sixth sub-electrode portion P6 is different from that of the fifth sub-electrode portion P5. The extension length b1 of the sixth sub-electrode portion P6 is greater than the extension length b2 of the fifth sub-electrode portion P5, and greater than the extension length b3 of the seventh sub-electrode portion P7. The extension length b2 of the fifth sub-electrode portion P5 may be equal to the extension length b3 of the seventh sub-electrode portion P7. In some embodiments, the extension length b1 of the sixth sub-electrode portion P6 may be 1.5 ~3 times the extension length b2 of the fifth sub-electrode portion P5. In some embodiments, the extension length b1 of the sixth sub-electrode portion P6 may be 2 times the extension length b2 of the fifth sub-electrode portion P5.

In some embodiments, as shown in FIG. 5A to FIG. 5J, the angle between the extension direction of the fifth sub-electrode portion P5 and the first direction X may be 40°~50°. For example, it may be 45°. The angle between the extension direction of the sixth sub-electrode portion P6 and the first direction X may be 130°~140°. For example, it may be 135°. The angle between the extension direction of seventh sub-electrode portion P7 and the first direction X may be 40°~50°. For example, it may be 45°.

As shown in FIG. 5A to FIG. 5J, the extension direction of slits F in the fifth sub-electrode portion P5 is the same as that of the fifth sub-electrode portion P5. The extension direction of slits F in the sixth sub-electrode portion P6 is the same as that of the sixth sub-electrode portion P6. The extension direction of slits F in the seventh sub-electrode portion P7 is the same as that of the seventh sub-electrode portion P7. In this way, the direction of edge electric field of the pixel electrode 4 is identical to the direction of the internal electric field of the pixel electrode 4, the liquid crystal disorder phenomenon is reduced or eliminated, the edge dark lines of the pixel electrode 4 are improved, and the color shift of the left-right view angles of the display panel is improved.

In some embodiments, the length of slits F in a direction perpendicular to the extension direction thereof may range from 2 μm to 4 μm. In some embodiments, the length of slits F may be 3 μm in the direction perpendicular to the extension direction thereof. In embodiments of the present disclosure, in the array substrate provided based on the embodiment of the present disclosure, when the length of the slits F is reduced to 3 μm in the direction perpendicular to the extension direction thereof, the dark lines almost disappear.

In some embodiments, as shown in FIG. 5A to FIG. 5J, the angle between the extension direction of the slits F of the fifth sub-electrode portion P5 and the first direction X may range from 40° to 50°. For example, it may be 45°. The angle between the extension direction of the slits F of the sixth sub-electrode portion P6 and the first direction X may range from 130° to 140°. For example, it may be 135°. The angle between the extension direction of the slits F of the seventh sub-electrode portion P7 and the first direction X may range from 40° to 50°. For example, it may be 45°.

In some embodiments, as shown in FIG. 5A to FIG. 5J, the data line includes: a ninth data portion 39 located on a side of the fifth sub-electrode portion P5 and extending in a direction same as the extension direction of the fifth sub-electrode portion P5, a tenth data portion 310 located on a side of the sixth sub-electrode portion P6 and extending in a direction same as the extension direction of the sixth sub-electrode portion P6, and an eleventh data portion 311 located on a side of the seventh sub-electrode portion P7 and extending in a direction same as the extension direction of the seventh sub-electrode portion P7. In this way, the curved shape of the data line 3 is consistent with the curved shape of the pixel electrode 4, so that the direction of the edge electric field of the pixel electrode 4 is identical to the direction of the internal electric field of the pixel electrode 4, the liquid crystal disorder phenomenon is reduced or eliminated, the edge dark lines of the pixel electrode 4 is improved, and the color shift of the left-right view angles of the display panel is improved.

Based on the same invention conception, the embodiment of the present disclosure also provides a display panel including the array substrate provided In embodiments of the present disclosure, further includes an opposing substrate opposite to the an array substrate, and the opposing substrate includes a common electrode layer.

In some embodiments, combined with FIG. 1H, FIG. 2J, FIG. 3J, FIG. 4J, FIG. 5J, the display panel may also be provided with a black matrix 8, and the orthographic projection of the black matrix 8 on the base substrate 1 may cover the orthographic projection of the gate line 2 on the base substrate 1, and cover the orthographic projection of the data line 3 on the base substrate 1. In some embodiments, the opposing substrate may include an opposing base substrate 90, and the black matrix 8 may be located between the opposing base substrate 90 and the common electrode layer (not shown in FIG. 10).

Based on the same invention conception, the embodiment of the present disclosure also provides a display device, which includes the display panel provided by embodiments of the present disclosure.

In embodiments of the present disclosure, the display device may be: a mobile phone, a tablet computer, a television, a monitor, a notebook computer, a digital photo frame, a navigator and any other product or component with a display function. The other indispensable components of the display device are those reasonably skilled in the art and should be understood, and are not described herein and should not be used as a limitation on the present disclosure.

Although preferred embodiments of the present invention have been described, those embodiments may be subject to additional changes and modifications once the basic inventive concepts are known to those skilled in the art. Therefore, the attached claims are intended to be construed to include the preferred embodiment and all changes and modifications that fall within the scope of the invention.

Obviously, a person skilled in the art may make various changes and variants to the embodiments of the present invention without departing from the spirit and scope of the embodiments of the present invention. Thus, if these modifications and variants of the embodiments of the present invention fall within the scope of the claims of the present invention and their equivalents, the present invention is also intended to include such modifications and variants.

What is claimed is:

1. An array substrate, comprising:
a base substrate;
a plurality of gate lines on a side of the base substrate, and extending along a first direction;
a plurality of data lines, wherein a main body direction of the plurality of data lines extends along a second direction, and an orthographic projection of each of the plurality of data lines on the base substrate is curved in shape;
a plurality of pixel electrodes, wherein an orthographic projection of the pixel electrodes on the base substrate is between orthographic projections of adjacent data lines on the base substrate; each pixel electrode comprises a plurality of slits, and an extension direction of an orthographic projection of the slits on the base substrate is identical to an extension direction of the orthographic projection of adjacent data line on the base substrate.

2. The array substrate of claim 1, wherein an orthographic projection of the gate lines on the substrate passes through an central area of the orthographic projection of the pixel electrodes on the base substrate;
each pixel electrode comprises a first gap in an area where the gate lines are located; each pixel electrode comprises: a first pixel electrode located on one side of the gate line, a second pixel electrode on the other side of the gate line, and a connecting portion connecting at least a part of the first pixel electrode with at least a part of the second pixel electrode;
wherein the array substrate further comprises: a plurality of transistors; wherein the pixel electrodes are electrically connected with the data lines through the plurality of transistors;
the first pixel electrode comprises: a first sub-pixel electrode distributed along the second direction, a second sub-pixel electrode distributed along the second direction;
the second pixel electrode comprises: a third sub-pixel electrode distributed along the second direction, a fourth sub-pixel electrode distributed along the second direction;
wherein the second sub-pixel electrode is located on one side the first sub-pixel electrode far away from the data line that is electrically connected with the first sub-pixel electrode, and the fourth sub-pixel electrode is located on one side of the third sub-pixel electrode far away from the data line that is electrically connected with the third sub-pixel electrode;
one of the first sub-pixel electrode and the second sub-pixel electrode is electrically connected with one of the third sub-pixel electrode and the fourth sub-pixel electrodes through the connecting portion;
wherein the first sub-pixel electrode and the fourth sub-pixel electrode are electrically connected through the connecting portion in a layer where the pixel electrodes are located; the second sub-pixel electrode is independent of the third sub-pixel electrode in the layer where the pixel electrodes are located.

3. (canceled)

4. (canceled)

5. The array substrate of claim 2, further comprising: a first common wire that is located on a side of the gate line and extends along the first direction; wherein the plurality of transistors comprises: a first transistor, a second transistor, and a third transistor;
a control electrode of the first transistor is electrically connected with the gate line, a first electrode of the first transistor is electrically connected with the data line, and a second electrode of the first transistor is electrically connected with the connecting portion;
a control electrode of the second transistor is electrically connected with the gate line, a first electrode of the second transistor is electrically connected with the data line, and a second electrode of the second transistor is electrically connected with the second sub-pixel electrode and the third sub-pixel electrode;
a control electrode of the third transistor is electrically connected with the gate line, the second electrode of the second transistor is multiplexed as a first electrode of the third transistor, and a second electrode of the third transistor is electrically connected with the first common wire.

6. The array substrate of claim 5, wherein the second electrode of the first transistor comprises: a first portion of the first transistor extending in the first direction;
the array substrate further comprises: a first lap portion connected with the connecting portion, an orthographic projection of the first lap portion on the substrate and an orthographic projection of the first portion of the first transistor portion on the substrate have an overlapping area;
wherein the connecting portion comprises: a first connecting portion extending along the first direction, a second connecting portion extending along the first direction, and a third connecting portion extending along the second direction;
one end of the first connecting portion is electrically connected with the first sub-pixel electrode, and the other end of the first connecting portion is electrically connected with one end of the third connecting portion; the other end of the third connecting portion is electrically connected with one end of the second connecting portion; the other end of the second connecting portion is electrically connected with the fourth sub-pixel electrode;
the first lap portion is electrically connected with one end of the first connecting portion which is far away from the first sub-pixel electrode connected with the first connecting portion;
wherein there is a second gap between the first connecting portion and the first sub-pixel electrode connected with the first connecting portion, and there is a third gap between the second connecting portion and the fourth sub-pixel electrode electrically connected with the second connecting portion.

7. (canceled)

8. (canceled)

9. (canceled)

10. The array substrate of claim 5, wherein the second electrode of the second transistor comprises: a first portion of a second transistor extending along the first direction and a second portion from which the first portion of the second transistor extends, of the second transistor extending along the second direction;
the array substrate further comprises: a first adapter extending along the first direction, a second adapter extending along the second direction, and a second lap section; one end of the first adapter is electrically connected with the second sub-pixel electrode, and the other end of the first adapter is electrically connected with one end of the second adapter; the other end of the second adapter is electrically connected with the second lap portion; an orthographic projection of the second portion of the second transistor on the substrate and an orthographic projection of the second lap portion on the substrate have an overlapping area;
the array substrate further comprises: a third adaptor along the first direction, and a third lap portion; one end of the third adapter is electrically connected with the third sub-pixel electrode, and the other end of the third adaptor is electrically connected with the third lap portion; an orthographic projection of the first portion of the second transistor on the substrate and an orthographic projection of the third lap portion on the substrate have an overlapping area;
wherein there is a fourth gap between the first adapter and the second sub-pixel electrode, and there is a fifth gap is between the third adapter and the third sub-pixel electrode.

11. (canceled)

12. (canceled)

13. The array substrate of claim 5, wherein the second electrode of the third transistor comprises: a first portion of the third transistor extending along the second direction, and a second portion from which the first portion of the third transistor extends, of the third transistor extending along the first direction;
the array substrate further comprises: a fourth lap portion; the first common wire comprises: a first-common-wire main portion and a first common lap portion connected with one end of the first-common-wire main portion;
an orthographic projection of the second portion of the third transistor on the base substrate and an orthographic projection of the fourth lap portion on the base substrate have an overlapping area; the orthographic projection of the first common lap portion on the base substrate and the orthographic projection of the fourth lap portion on the base substrate have an overlapping area.

14. The array substrate of claim 13, wherein the fourth lap portion comprises an outer edge of the fourth lap portion along the first direction, and the second lap portion comprises an outer edge of the second lap portion extending along the first direction;
an extension line of the outer edge of the fourth lap portion coincides with an extension line of the outer edge of the second lap portion;
wherein the first lap portion comprises an outer edge of the first lap portion extending along the second direction, and the third lap portion comprises an outer edge of the third lap portion extending along the second direction;
an extension line of the outer edge of the first lap portion coincides with an extension line of the outer edge of the third lap portion.

15. (canceled)

16. The array substrate of claim 5, further comprising: a second common wiring group that is electrically connected with the first common wire and extends away from a side of the gate lines, wherein the second common wiring group comprises: two second common wires; the orthographic projection of the data lines on the base substrate and orthographic projections of a gap between the two second common wires in the same second common wiring group on the base substrate have an overlapping areas; the orthographic projection of the second common wire on the substrate is curved shape, and the curved shape of the orthographic projection of the second common wire on the base substrate is identical to the curved shape of the orthographic projection of the data lines on the base substrate; or
wherein the array substrate further comprises: a third common wire that is located on the other side of the gate line and extends along the first direction, and a fourth common wiring group that is connected with the third common wire and extends far away from a side of the gate line; the third common wire is disconnected at a position where the third common wire intersects with the data lines; the fourth common wiring group comprises: two fourth common wires, the orthographic projection of the data lines on the base substrate and an orthographic projection of a gap between the two fourth common wires of the same fourth common wiring group on the base substrate have an overlapping area; the orthographic projection of the fourth common wire on the base substrate is curved shape, and the curved shape of the orthographic projection of the fourth common wire on the base substrate is identical to the curved shape of the orthographic projection of the data line on the base substrate.

17. (canceled)

18. The array substrate of claim 2, wherein the first pixel electrode is an integrated structure, and the second pixel electrode is an integrated structure.

19. The array substrate of claim 18, wherein one end far away from the gate lines, of the first pixel electrode is an opening; one end far away from the gate lines, of the second pixel electrode is an opening;
wherein each gate line comprises a gate line hollow, an orthographic projection of the gate line hollow on the base substrate covers at least a part of the orthographic projection of the connecting portion on the base substrate.

20. (canceled)

21. (canceled)

22. The array substrate of claim 2, wherein the first pixel electrode comprises: a first sub-electrode portion distributed along the second direction, and a second sub-electrode portion distributed along the second direction, and an extension direction of the first sub-electrode portion is different from an extension direction of the second sub-electrode portion;
the second pixel electrode comprises: a third sub-electrode portion along the second direction, and a fourth sub-electrode portion along the second direction; an extension direction of the third sub-electrode portion is different from an extension direction of the fourth sub-electrode portion.

23. The array substrate of claim 22, wherein the extension direction of the first sub-electrode portion is identical to the extension direction of the fourth sub-electrode portion; the extension direction of the second sub-electrode portion is identical to the extension direction of the third sub-electrode portion; or
wherein the extension direction of the first sub-electrode portion is identical to the extension direction of the third sub-electrode portion; the extension direction of the second sub-electrode portion is identical to the extension direction of the fourth sub-electrode portion.

24. (canceled)

25. (canceled)

26. The array substrate of claim 22, wherein each data line comprises:
a first data portion located on a side of the first sub-electrode portion and extending in a direction same as the extension direction of the first sub-electrode portion;
a second data portion located on one side of the second sub-electrode portion and extending in a direction same as the extension direction of the second sub-electrode portion;
a third data portion located on one side of the third sub-electrode portion and extending in a direction same as the extension direction of the third sub-electrode portion; and
a fourth data portion located on one side of the fourth sub-electrode portion and extending in a direction same as the extension direction of the fourth sub-electrode portion;
wherein each data line further comprises: a fifth data portion extending along the second direction and connecting the second data portion with the third data portion.

27. (canceled)

28. The array substrate of claim 18, wherein the first pixel electrode and the second pixel electrode extend along a third direction, and an outer edge of the first pixel electrode in the extension direction does not coincide with an outer edge of the second pixel electrode in the extension direction.

29. The array substrate of claim 28, wherein each data line comprises: a sixth data portion arranged at a side of the first pixel electrode and a seventh data portion arranged at a side of the second pixel electrode;
an extension direction of the sixth data portion is identical to an extension direction of the seventh data portion, and an extension line of the sixth data portion does not coincide with an extension line of the seventh data portion;
wherein each data line further comprises: an eighth data portion extending along the second direction and connecting the sixth data portion with the seventh data portion.

30. (canceled)

31. The array substrate of claim 1, wherein the orthographic projection of the gate line on the base substrate is on a side of the orthographic projection of the pixel electrode on the base substrate.

32. The array substrate of claim 31, further comprising: a first conductive layer arranged on a side facing the base substrate, of the pixel electrode, and a fifth common wire in a layer same as the layer where the gate liens are located; the first conductive layer is electrically connected with the fifth common wire through a conduction hole;
wherein the fifth common wire comprises a first common convex portion on a side facing the gate lines, of the fifth common wire; at least parts of orthographic projection of the first common convex portion on the base substrate overlaps at least parts of orthographic projection of the conduction hole on the base substrate;
wherein each gate line comprises a first notch on a side facing the fifth common wire, of the gate line, the first notch is opposite to the first common convex portion;
wherein one side of the pixel electrode is provided with a fifth lap portion;
each gate line comprises a second notch on a side facing the fifth common wire, of the gate line; an orthographic projection of the second notch on the base substrate covers the orthographic projection of the fifth lap portion on the base substrate.

33. (canceled)

34. (canceled)

35. (canceled)

36. The array substrate of claim 31, wherein each pixel electrode comprises: a first sub-electrode portion, a second sub-electrode portion, a third sub-electrode portion, and a fourth sub-electrode portion sequentially distributed in the second direction;
an extension direction of the first sub-electrode portion is different from an extension direction of the second sub-electrode portion; an extension direction of the third sub-electrode portion is different from an extension direction of the fourth sub-electrode portion;
wherein the extension direction of the first sub-electrode is identical to the extension direction of the fourth sub-electrode portion; the extension direction of the second sub-electrode portion is identical to the extension direction of the third sub-electrode portion;
wherein each data line comprises:
a first data portion located on a side of the first sub-electrode portion and extending in a direction same as the extension direction of the first sub-electrode portion;
a second data portion located on a side of the second sub-electrode portion and extending in a direction same as the extension direction of the second sub-electrode portion;
a third data portion located on a side of the third sub-electrode portion and extending in a direction same as the extension direction of the third sub-electrode portion; and
a fourth data portion located on a side of the fourth sub-electrode portion and extending in a direction same as the extension direction of the fourth sub-electrode portion;
wherein the second data portion is directly connected with the third data portion.

37. (canceled)

38. (canceled)

39. The array substrate of claim 31, wherein each pixel electrode comprises: a fifth sub-electrode portion, a sixth sub-electrode portion, and a seventh sub-electrode portion which are distributed in sequence in the second direction; an extension direction of the fifth sub-electrode portion is identical to an extension direction of the seventh sub-electrode portion; an extension direction of the sixth sub-electrode portion is different from the extension direction of the fifth sub-electrode portion;
an extension length of the sixth sub-electrode portion is greater than an extension length of the fifth sub-electrode portion, and the extension length of the sixth sub-electrode portion is greater than an extension length of the seventh sub-electrode portion;
wherein each data line comprises:
a ninth data portion located on a side of the fifth sub-electrode portion and extending in a direction same as the extension direction of the fifth sub-electrode portion;
a tenth data portion located on a side of the sixth sub-electrode portion and extending in a direction same as the extension direction of the sixth sub-electrode portion; and
an eleventh data portion located on a side of the seventh sub-electrode portion and extending in a direction same as the extension direction of the seventh sub-electrode portion.

40. (canceled)

41. A display panel, comprising the array substrate claim 1, and further comprising an opposing substrate arranged as opposed to the array substrate, wherein the opposing substrate comprises a common electrode layer.

42. (canceled)
